(19) United States
(12) Patent Application Publication
(10) Pub. No.: US 2017/0133597 A1
(43) Pub. Date: May 11, 2017

(54) SEMICONDUCTING POLYMERS WITH MOBILITY APPROACHING ONE HUNDRED SQUARE CENTIMETERS PER VOLT PER SECOND

(71) Applicant: The Regents of the University of California, Oakland, CA (US)

(72) Inventors: Byoung Hoon Lee, Goleta, CA (US); Ben B. Y. Hsu, Santa Barbara, CA (US); Chan Luo, Santa Barbara, CA (US); Ming Wang, Goleta, CA (US); Guillermo C. Bazan, Santa Barbara, CA (US); Alan J. Heeger, Santa Barbara, CA (US)

(73) Assignee: The Regents of the University of California, Oakland, CA (US)

(21) Appl. No.: 15/349,920

(22) Filed: Nov. 11, 2016

Related U.S. Application Data
(60) Provisional application No. 62/253,975, filed on Nov. 11, 2015.
(60) Provisional application No. 62/263,058, filed on Dec. 4, 2015.

(51) Int. Cl. H01L 51/00; C08G 61/12

(52) U.S. Cl. CPC H01L 51/0036; C08G 61/126; H01L 51/0043; H01L 51/0558

(57) ABSTRACT

One or more embodiments of the present invention report here a comparative study of field effect transistors (FETs) fabricated with semiconducting polymer PBT, regioregular semiconducting polymers, PCDTPT and their fluorinated analogue (P2F, PCDTFBT), in the transistor channel. The present invention shows that simple fluorination of PBT and PCDTPT to PCDTFBT leads to air-stability and reliable transistor characteristics. The FETs fabricated from aligned PCDTFBT yielded stable threshold voltages (at zero volt) and a narrow distribution of saturation hole mobilities of 65 cm² V⁻¹ s⁻¹ (average over 50 independent FET devices). At higher source-drain voltage (higher electric field in the channel) the mobility approaches 100 cm² V⁻¹ s⁻¹, the highest value for semiconducting polymers reported to date. High mobility is retained over 150 hours in ambient air without any encapsulation layers. The results obtained in one or more embodiments of the invention represent important progress for solution-processed plastic transistors, and provide molecular design guidelines for high-mobility and air-stable conjugated polymers.

### CROSS REFERENCE TO RELATED APPLICATIONS

This application claims the benefit under 35 U.S.C. Section 119(e) of the following co-pending and commonly-assigned applications:

U.S. Provisional Patent Application No. 62/253,975, filed Nov. 11, 2015, by Ming Wang and Guillermo Bazan, entitled “FLUORINE SUBSTITUTION INFLUENCE ON BENZO[2,1,3]THIODIAZOLE BASED POLYMERS FOR FIELD-EFFECT TRANSISTOR APPLICATIONS,” Attorney's Docket No., 30794.607-US-P1 (2016-316); and

U.S. Provisional Patent Application No. 62/263,058, filed Dec. 4, 2015, by Byoung Hoon Lee, Ben B. Y. Hsu, Chan Luo, Ming Wang, Guillermo Bazan, and Alan J. Heeger, entitled “SEMICONDUCTING POLYMERS WITH MOBILITY APPROACHING ONE HUNDRED SQUARE CENTIMETERS PER VOLT PER SECOND,” Attorney's Docket No. 30794.598-US-P1 (U.C. Ref. 2016-239-1);

both of which applications are incorporated by reference herein.

This application is related to the following co-pending and commonly-assigned U.S. patent applications:

U.S. Provisional Patent Application No. 62/367,401, filed Jul. 27, 2016, by Colin R. Bridges, Michael J. Ford, Guillermo C. Bazan, and Rachel A. Segalman, entitled “FORMATION AND STRUCTURE OF LYOTROPIC LIQUID CRYSTALLINE MESOPHASES IN DONOR-ACCEPTOR SEMICONDUCTING POLYMERS,” Attorney's Docket No., 30794.623-US-P1 (UC Ref 2016-607-1);

U.S. Provisional Patent Application No. 62/338,866, filed May 19, 2016, by Michael J. Ford, Hengbin Wang, and Guillermo Bazan, entitled “ORGANIC SEMICONDUCTOR SOLUTION BLENDS FOR SWITCHING AMBIPOLAR TRANSPORT TO N-TYPE TRANSPORT,” Attorney's Docket No., 30794.619-US-P1 (UC Ref 2016-607-1); U.S. Provisional Patent Application No. 62/327,311, filed Apr. 25, 2016, by Guillermo Bazan and Ming Wang, entitled “NOVEL WEAK DONOR-ACCEPTOR CONJUGATED COPOLYMERS FOR FIELD-EFFECT TRANSISTOR APPLICATIONS,” Attorney's Docket No., 30794.616-US-P1 (UC Ref. 2016-609-1);

U.S. Provisional Patent Application No. 62/276,145, filed Jan. 7, 2016, by Michael J. Ford and Guillermo Bazan, entitled “STABLE ORGANIC FIELD-EFFECT TRANSISTORS BY INCORPORATING AN ELECTRON-ACCEPTING MOLECULE,” Attorney's Docket No., 30794.608-US-P1;

U.S. Utility patent application Ser. No. 15/256,160, filed Sep. 2, 2016, by Byoung Hoon Lee and Alan J. Heeger, entitled “DOPING-INDUCED CARRIER DENSITY MODULATION IN POLYMER FIELD-EFFECT TRANSISTORS,” Attorney's Docket No. 30794.595-US-P1 (U.C. Ref. 2016-115), which application claims the benefit under 35 U.S.C. Section 119(e) of co-pending and commonly-assigned U.S. Provisional Patent Application No. 62/214,076, filed Sep. 3, 2015, by Byoung Hoon Lee and Alan J. Heeger, entitled “DOPING-INDUCED CARRIER DENSITY MODULATION IN POLYMER FIELD-EFFECT TRANSISTORS,” Attorney's Docket No. 30794.595-US-P1 (U.C. Ref. 2016-115-1);

U.S. Utility patent application Ser. No. 15/241,949 filed Aug. 19, 2016, by Michael Ford and Guillermo Bazan, entitled “HIGH MOBILITY POLYMER ORGANIC FIELD-EFFECT TRANSISTORS BY BLADE-COATING SEMICONDUCTOR: INSULATOR BLEND SOLUTIONS,” Attorney's Docket No. 30794.592-US-U1 (U.C. Ref 2016-112), which application claims the benefit under 35 U.S.C. Section 119(e) of U.S. Provisional Patent Application No. 62/207,707, filed Aug. 20, 2015, by Michael Ford and Guillermo Bazan, entitled “HIGH MOBILITY POLYMER ORGANIC FIELD-EFFECT TRANSISTORS BY BLADE-COATING SEMICONDUCTOR: INSULATOR BLEND SOLUTIONS,” Attorney's Docket No. 30794.592-US-P1 (U.C. Ref. 2016-112-1); and U.S. Provisional Patent Application No. 62/262,025, filed Dec. 2, 2015, by Michael Ford and Guillermo Bazan, entitled “HIGH MOBILITY POLYMER ORGANIC FIELD-EFFECT TRANSISTORS BY BLADE-COATING SEMICONDUCTOR: INSULATOR BLEND SOLUTIONS,” Attorney's Docket No. 30794.592-US-P2 (U.C. Ref. 2016-112-2);

U.S. Utility application Ser. No. 15/213,029 filed on Jul. 18, 2016 by Byoung Hoon Lee and Alan J. Heeger, entitled “FLEXIBLE ORGANIC TRANSISTORS WITH CONTROLLED NANOMORPHOLOGY”, Attorney's Docket No. 30794.0589-US-U1 (UC Ref 2015-977-1), which application claims the benefit under 35 U.S.C. Section 119(e) of U.S. Utility U.S. Provisional Application Ser. No. 62/193,909 filed on Jul. 17, 2015 by Byoung Hoon Lee and Alan J. Heeger, entitled “FLEXIBLE ORGANIC TRANSISTORS WITH CONTROLLED NANOMORPHOLOGY”, Attorney's Docket No. 30794.0589-US-P1 (UC Ref. 2015-977-1);

U.S. Utility patent application Ser. No. 15/058,994, filed Mar. 2, 2016, by Shrayesh N. Patel, Edward J. Kramer, Michael L. Chabinyc, Chan Luo and Alan J. Heeger, entitled “BLADE COATING ON NANOGROOVED SUBSTRATES YIELDING ALIGNED THIN FILMS OF HIGH MOBILITY SEMICONDUCTING POLYMERS,” Attorney's Docket No. 30794.583-US-P1 (U.C. Ref 2015-437), which Application claims the benefit under 35 U.S.C. Section 119(e) of U.S. Provisional Patent Application No. 62/127,116, filed Mar. 2, 2015, by Shrayesh N. Patel, Edward J. Kramer, Michael L. Chabinyc, Chan Luo and Alan J. Heeger, entitled “BLADE COATING ON NANOGROOVED SUBSTRATES YIELDING ALIGNED THIN FILMS OF HIGH MOBILITY SEMICONDUCTING POLYMERS,” Attorney's Docket No. 30794.583-US-P1 (U.C. Ref 2015-437);

U.S. Utility patent application Ser. No. 14/585,653, filed on Dec. 30, 2014, by Chan Luo and Alan Heeger, entitled “HIGH MOBILITY POLYMER THIN FILM TRANSISTORS WITH CAPILLARITY MEDIATED SELF-ASSEMBLY”, Attorney's Docket No. 30794.537-US-U1 (UC Ref 2014-337), which application claims the benefit under 35 U.S.C. Section 119(e) of co-pending U.S. Provisional Patent Application Ser. No. 61/923,452, filed on Jan. 3, 2014, entitled “HIGH MOBILITY POLYMER THIN FILM TRANSISTORS WITH CAPILLARITY MEDIATED SELF-ASSEMBLY,” Attorney's Docket No. 30794.537-US-P1 (UC Ref 2014-337);

U.S. Utility patent application Ser. No. 14/426,467, filed on Mar. 6, 2015, by Hsing-Rong Tseng, Lei Ying, Ben B. Y. Hsu, Christopher J. Takacs, and Guillermo C. Bazan, entitled “FIELD-EFFECT TRANSISTORS BASED ON MACROSCOPICALLY ORIENTED POLYMERS,” which application claims the benefit under 35 U.S.C. §365 of PCT International patent application serial no. PCT/US13/058546 filed Sep. 6, 2013, which application claims the benefit under 35 U.S.C. Section 119(e) of co-pending U.S. Provisional Patent Application Ser. Nos. 61/698,065, filed on Sep. 7, 2012, and 61/863,255, filed on Aug. 7, 2013, entitled “FIELD-EFFECT TRANSISTORS BASED ON MACROSCOPICALLY ORIENTED POLYMERS,” (UC REF 2013-030); and

U.S. Utility patent application Ser. No. 13/526,371, filed on Jun. 18, 2012, by G. Bazan, L. Ying, B. Hsu, W. Wen, H-R Tseng, and G. Welch entitled “REGIOREGULAR PYRIDAL[2,1,3]THIADIAZOLE PI-CONJUGATED COPOLYMERS FOR ORGANIC SEMICONDUCTORS” (Attorney Docket No. 1279-543 and U.C. Docket No. 2011-577-3), which application claims priority under 35 U.S.C. §119(e) to U.S. Provisional Patent Application Ser. No. 61/498,390, filed on Jun. 17, 2011, by G. Bazan, L. Ying, B. Hsu, and G. Welch entitled “REGIOREGULAR CONSTRUCTIONS FOR THE SYNTHESIS OF THIADIAZOLO (3,4) PYRIDINE CONTAINING NARROW BAND GAP CONJUGATED POLYMERS” (Attorney Docket No. 1279-543P and U.C. Docket No. 2011-577-1) and U.S. Provisional Patent Application Ser. No. 61/645,970, filed on May 11, 2012, by G. Bazan, L. Ying, and Wen, entitled “REGIOREGULAR PYRIDAL[2,1,3]THIADIAZOLE PI-CONJUGATED COPOLYMERS FOR ORGANIC SEMICONDUCTORS” (Attorney Docket No. 1279-543P2 and U.C. Docket No. 2011-577-2);

all of which applications are incorporated by reference herein.

### STATEMENT REGARDING FEDERALLY SPONSORED RESEARCH AND DEVELOPMENT

This invention was made with Government support under Grant Nos. DMR 0856060 and DMR 1436263 awarded by the National Science Foundation to Alan J. Heeger.

### BACKGROUND OF THE INVENTION

1. Field of the Invention

This invention relates to high mobility organic field effect transistors (OFETs).

2. Description of the Related Art

(Note: This application references a number of different publications as indicated throughout the specification by one or more reference numbers in parentheses, e.g., (x). A list of these different publications ordered according to these reference numbers can be found below in the section entitled “References.” Each of these publications is incorporated by reference herein.)

Despite nearly three decades of materials development, poor performance and instability of semiconducting polymers developed to date limit practical applications. One or more embodiments of the present invention overcome these problems.

### SUMMARY OF THE INVENTION

One or more embodiments of the present invention describe various semiconductor polymers comprising fluorinated conjugated polymer chains, one or more methods for fabricating the semiconducting polymers, and one or more devices incorporating the semiconducting polymers.

The devices and methods are embodied in many ways, including, but not limited to, the following embodiments 1-24 listed below.

1. One or more organic field effect transistors (OFETs) comprising a channel, the channel comprising the semiconducting polymers, and wherein each of the semiconducting polymers have a repeating unit of the structure:

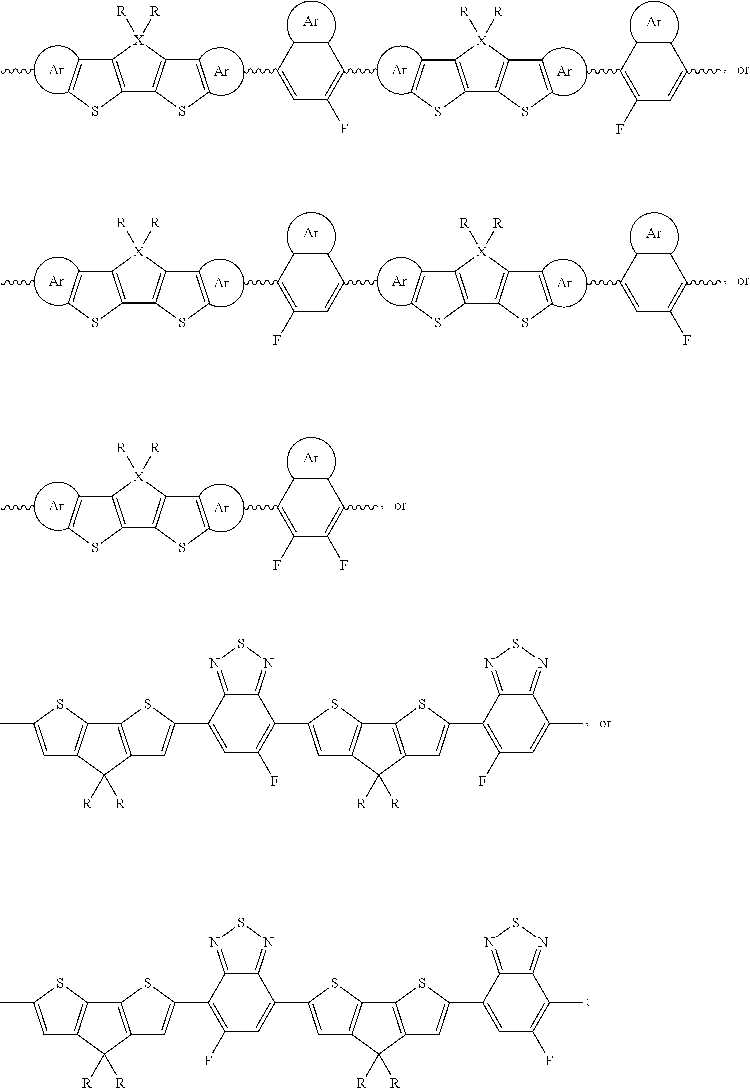

and

wherein the fluorine (F) is regioregularly arranged along the semiconducting polymer's conjugated main chain section and the R are each independently an alkyl, aryl, or an alkoxy chain. The OFETs each further comprise a source contact to the channel; a drain contact to the channel; and a gate contact under, below, on or above the channel.

2. The OFETs of the first embodiment 1, wherein the semiconducting polymers are disposed in a film on a planar, non-grooved surface/substrate/dielectric, wherein the film has a crystallinity characterized by the OFETs each having a hole mobility of at least 1.2 cm²V⁻¹ s⁻¹ (e.g., in a range of 1.2-10 cm²V⁻¹ s⁻¹) in a saturation regime.

3. The OFETs of any of the preceding embodiments, wherein the OFETs' mobility is not dependent on blade coating direction.

4. The OFETs of any of the preceding embodiments, wherein the semiconducting polymers are not aligned or there is no clear alignment of the semiconducting polymers as measured in top surface of an atomic force microscope (AFM) image of the semiconducting polymers.

5. The OFETs of the first embodiment, wherein the semiconducting polymers are on a grooved surface/substrate/dielectric and have an alignment with respect to each other characterized by the OFETs each having a hole mobility between 1 cm² V⁻¹ s⁻¹ and 97 cm² V⁻¹ s⁻¹, in a saturation regime.

6. The OFETs of embodiment 5 each having a threshold voltage within +/−1 volt of zero volts.

7. The OFETs of embodiment 5 each having a threshold voltage of zero volts.

8. The OFETs of any of the embodiments 5-7 wherein the semiconducting polymers comprise aligned conjugated polymer chains stacked to form a crystalline structure, the polymer chains oriented with an orientational order parameter between 0.9 and 1.

9. The OFETs of any of the embodiments 5-8, wherein a π-π stacking of the semiconducting polymer chains in the film is characterized by a peak having a full width at half maximum of 2 nm⁻¹ or less, as measured by a grazing incidence wide-angle X-ray scattering (GIWAXS) measurement of the film.

10. The OFETs of any of the preceding embodiments 2-9, wherein a π-π distance between adjacent polymer chains is no more than 0.35 nm.

11. A device comprising storage for a plurality (e.g., at least twenty or at least fifty) of the OFETs of any of the preceding embodiments, wherein each of the OFETs are characterized by: a threshold voltage such that an average threshold voltage for the twenty OFETs is within +/−1 volt of zero volts.

12. The OFETs of any of the preceding embodiments, wherein each of the OFETs are characterized by having a threshold voltage that is stable (e.g., within +/−1 V of zero volts) after multiple sweeps of the gate source voltage.

13. The OFETs of any of the preceding embodiments, wherein each of the OFETs are characterized by having a stable threshold voltage at various operating voltages (e.g., the threshold voltage of each of the OFETs is within +/−1 V of zero volts when the gate source voltage varies between −120 V to −0.5 V).

14. A device of any of the preceding embodiments, wherein a stability of each of the OFETs is further characterized by the fifty OFETs having an average carrier mobility of at least 65 cm² V⁻¹ s⁻¹, in a saturation regime.

15. A device of any of the preceding embodiments, wherein the storage exposes the semiconducting polymers to air.

16. A device of any of the preceding embodiments, wherein the device comprises an optoelectronic or electronic device storing the OFETs in a circuit, and the OFETs do not comprise encapsulation layers or the semiconducting polymers are covered by layers permeable to air.

17. A device of any of the preceding embodiments, wherein a carrier mobility of each of the OFETs is reduced by less than 20% as exposure of the OFETs is increased from 4 hours to 100 hours in ambient air at a temperature of 22° C.-30° C., the ambient air having a relative humidity of 45%-70%, and the exposure including 50 hours in a nitrogen ambient.

18. A device of any of the preceding embodiments, wherein carrier (hole and/or electron) mobility of each of the OFETs is at least 0.03 cm²V⁻¹ s⁻¹ after exposure of the OFETs to the air for 5 days.

19. A device of any of the preceding embodiments, wherein the source and drain contacts of the OFETs further comprise a metal oxide electron blocking layer.

20. A device of embodiment 19, wherein the metal comprises nickel, silver, or Molybdenum.

21. A method of fabricating the OFETs of any of the preceding embodiments, wherein at least fifty of the OFETs are solution processed onto a substrate from a same batch of solution comprising the semiconducting polymers.

22. The method of claim 21, wherein the semiconducting polymers are deposited from solution onto a substrate to form a film comprising the semiconducting polymers, wherein a plurality of source contacts, a plurality of drain contacts, and a plurality of gate contacts are patterned onto the film to form a plurality of the OFETs each comprising a source, a drain, and a gate.

23. The OFETs of any of the preceding embodiments, wherein the OFETs (e.g., 50 OFETs) have a mean mobility between 1 and 100 cm²V⁻¹ s⁻¹ having a standard deviation of 13 cm²V⁻¹ s⁻¹ or less.

24. A circuit comprising the OFETs of any of the preceding embodiments, wherein the circuit comprises electrical connections switching the OFETs on or off using a voltage that is greater than or less than the threshold voltage of the OFETs (wherein the threshold voltage is zero volts or within +/−1 of zero volts.

### BRIEF DESCRIPTION OF THE DRAWINGS

Referring now to the drawings in which like reference numbers represent corresponding parts throughout:

FIG. 1 illustrates a scheme for polymer synthesis according to one or more embodiments of the present invention.

FIG. 2(a) illustrates UV-vis absorption of polymers in chlorobenzene solution and FIG. 2(b) illustrates UV-vis absorption of polymers in thin films, according to one or more embodiments of the present invention.

FIG. 2(c) illustrates GIWAXS measurement out of plane line-cut profiles and FIG. 2(d) illustrates GIWAXS measurement in plane line-cut profiles, of non-aligned semiconducting polymers (or semiconducting polymers with no clear alignment as measured in a top surface of an AFM image of the semiconducting polymers) according to one or more embodiments of the present invention.

FIGS. 3(a)-3(d) illustrate output curves of four polymer devices comprising non-aligned semiconducting polymers (or semiconducting polymers with no clear alignment as measured in a top surface of an AFM image of the semiconducting polymers) according to one or more embodiments of the present invention.

FIG. 4 plots polymer OFET mobilities tested in ambient condition, wherein the semiconducting polymers are non-aligned (or have no clear alignment as measured in a top surface of an AFM image of the semiconducting polymers) according to one or more embodiments of the present invention.

FIG. 5(a)-5(c) illustrates materials, UV-Vis-NIR absorption spectra, and XPS spectra of polymers according to one or more embodiments of the present invention, wherein FIG. 5(a) shows molecular structures of PCDTPT and PCDTFBT (the reactive nitrogen (in PCDTPT) and substituted fluorine (in PCDTFBT) are highlighted in grey and red, respectively), FIG. 5(b) shows normalized UV-Vis-NIR absorption spectra of PCDTPT and PCDTFBT thin films fabricated on quartz substrates (the inset shows the (αω)^{1/2} versus ω spectra of PCDTPT and PCDTFBT thin films, where dashed lines denote extrapolation of linear regime in each spectrum), and FIG. 5(c) shows XPS spectra of PCDTPT and PCDTFBT thin films prepared on gold substrates (the dashed line at 399.9 eV denotes N is core level originated from nitrogen in thiadiazole unit).

FIGS. 6(a)-6(e) show 2D GIWAXS patterns and line profiles according to one or more embodiments of the present invention, wherein FIGS. 6(a)-6(d) show 2D GIWAXS patterns of aligned PCDTPT (FIG. 6(a) and FIG. 6(b)) and PCDTFBT (FIGS. 6(c) and 6(d)) thin films prepared on nano-grooved silicon substrates (the perpendicular and parallel in parentheses denote incident beam directions relative to nano-grooves), and FIG. 6(e) shows 2D GIWAXS line profiles of the PCDTPT and PCDTFBT thin films using constant, grazing incident angle with in-plane and out-of-plane scattering geometries (the intensities are normalized to incident photon energy, q denotes the scattering vector, and the dashed line at q˜17.8 nm⁻¹ denotes intermolecular π-π stacking for both semiconducting polymers.

FIGS. 7(a)-7(e) illustrate transistor characteristics, wherein FIG. 7(a) shows transfer curves (log scale) of 5 representative FETs fabricated from aligned PCDTPT or PCDTFBT thin films on nano-grooved SiO₂ substrates as gate dielectrics taken at V_{DS}=−120 V (W/L=1,000/200 μm) (the transfer curves of one of the best devices are highlighted in grey (for PCDTPT) and red (for PCDTFBT), respectively); FIG. 7(b) shows transfer curves (square root scale) of one of the best devices fabricated from aligned PCDTPT (grey) and PCDTFBT (red) thin films. FIG. 7(c) shows output curves of one of the best devices with aligned PCDTPT (grey) and PCDTFBT (red) thin films taken at various V_{GS}, FIG. 7(d) shows V_{T} distribution for 50 FETs with aligned PCDTPT (square) or PCDTFBT (circle) extracted from the transfer curves taken at V_{DS}=−120 V, and FIG. 7(e) shows mobility distribution for 50 FETs with aligned PCDTPT (grey) or PCDTFBT (red) extracted from the transfer curves taken at V_{DS}=−120 V (for statistical data shown in FIGS. 7(d) and 7(e), data obtained from the device with channel lengths of 160 μm and 180 μm were also used.

FIGS. 8(a)-8(d) illustrate electrical stability and electric field dependent mobility of OFET devices according to one or more embodiments, wherein FIG. 8(a) shows transfer curves of devices fabricated with aligned PCDTPT and FIG. 8(b) shows transfer curves of devices fabricated with aligned PCDTFBT (Au/Ni source and drain electrodes were used, transfer curves were collected with continuous sweeping (solid lines) and after storage of devices in nitrogen for 1 h (dashed lines), FIG. 8(c) shows transfer curves of the best PCDTFBT device taken at various V_{DS} from −120 V to −0.5 V (the inset shows V_{T} values plotted as a function of V_{DS}), FIG. 8(d) is a mobility plot (average over 5 independent FETs) as a function of various electric fields (the highest saturation hole mobility of PCDTFBT is approximately 97 cm²/V-s taken at V_{DS}=−120 V, corresponding electric field: 6 kV cm⁻¹, and error bars denote standard deviation).

FIGS. 9(a)-9(c) illustrate thermal and air stability of OFET devices according to one or more embodiments, wherein FIG. 9(a) plots mobility variations of devices fabricated from aligned PCDTPT (grey) and PCDTFBT (red) as a function of various annealing temperatures. Error bars denote standard deviation, FIG. 9(b) plots transfer curves of devices, obtained at V_{DS}=−40 V, with aligned PCDTPT (grey) and PCDTFBT (red) thin films after annealing at 400° C. for 1 min, and FIG. 9(c) plots mobility variations of devices with aligned PCDTPT (grey) and PCDTFBT (red) as a function of storage time in ambient air. The grey boxes represent sample storage in a nitrogen-filled glove box. Error bars denote standard deviation.

FIG. 10 is a flowchart illustrating a method of fabricating an OFET according to one or more embodiments of the invention.

FIG. 11a illustrates examples for the ring unit comprising Fluorine in the semiconducting polymer, according to one or more embodiments of the present invention.

FIGS. 11b-11d illustrate examples for the dithiophene unit in the semiconducting polymers according to one or more embodiments of the present invention.

FIG. 12 is a flowchart illustrating a method of fabricating semiconducting polymers according to one or more embodiments of the present invention.

FIG. 13 illustrates an OFET according to one or more embodiments of the invention.

FIG. 14 illustrates a device comprising storage for a plurality of OFETs, including source and drain contacts/connections for the OFETs, according to one or more embodiments of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### TECHNICAL DESCRIPTION

Solution-processed OFETs are under intense investigation because of the potential they offer in terms of production costs and fabrication of flexible, light-weight substrates (28). Saturation regime mobilities of over 10 cm² v⁻¹ s⁻¹ have been achieved through coupled developments in molecular design strategies and improvements in film processing methods (29). Conjugated polymers containing a backbone with alternating donor-acceptor units comprise one of the most important approaches for achieving high mobility organic semiconductors used as the OFET transport material (30). Such structures consist of an electron rich moiety (donor, D) and an electron deficient moiety (acceptor, A) in each repeat unit. For example, Millen et al. developed a polymer containing 4,4-dihexadecyl-4H-cyclopenta[1,2-b:5,4-b′]dithiophene (CDT) as the donor unit and benzo[2,1,3]thiadiazole (BT) as the acceptor unit (31), namely PBT in Scheme 1 (CDTBTZ in the original publication), which was shown to be suitable for thin film alignment thereby able to attain mobility of 6.5 cm²V⁻¹ s⁻¹ (32). The molecular structure has been further refined by substituting the BT unit with a [1,2,5]thiadiazolo[3,4-c]pyridine (PT) unit through synthetic protocols that yield regioregular backbone structures (33). This regioregular polymer PCDTPT has yielded some of the highest mobilities in the literature (over 20 cm²V⁻¹ s⁻¹) through molecular weight control and novel film processing techniques that improve chain alignment (29(d)).

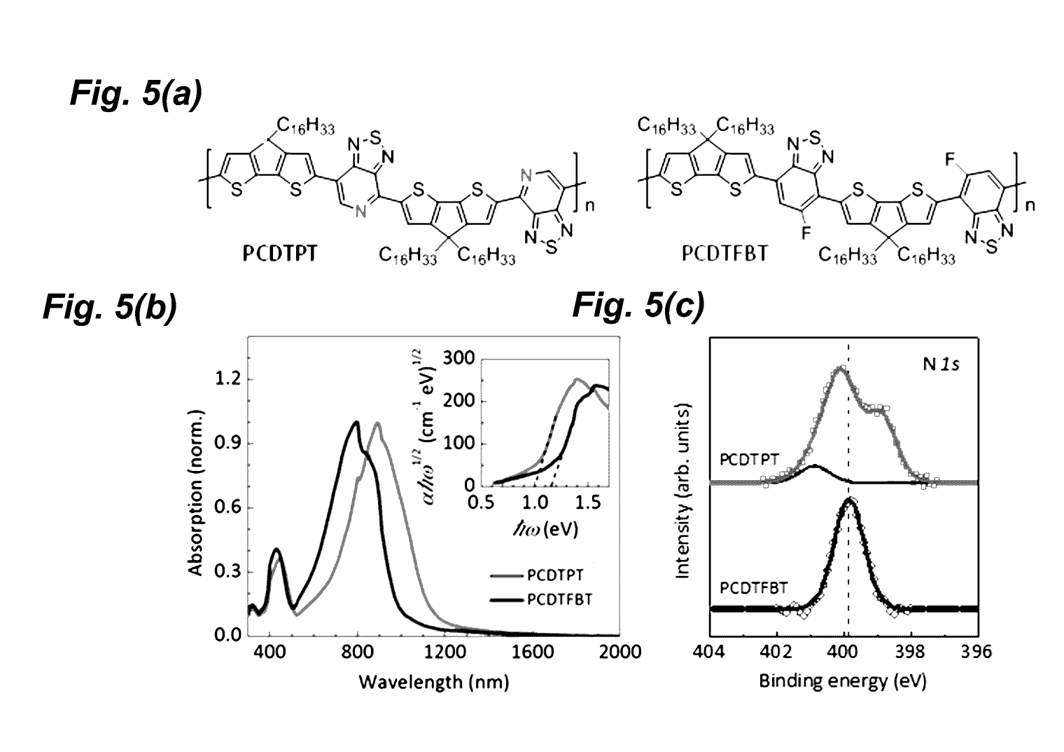

Indeed, the realization of π-electron wavefunctions delocalized over many repeat units along the backbone of highly aligned semiconducting polymer chains with minimal structural disorder is a primary requirement for achieving high mobility in semiconducting polymers (1, 2). To achieve this goal, one or more of the inventors of the present invention developed a series of crystalline semiconducting polymers including asymmetric regioregular PCDTPT (see FIG. 5a for the molecular structure) (3), which resulted in high chain alignment and high mobility, >50 cm²/V-s, through directed self-assembly of the semiconducting polymer chains guided by nano-grooves in the substrate onto which the polymer solution was cast (4-6). The flat, rigid molecular framework of PCDTPT enables a high degree of orientation, leading to intrachain ii-electronic wavefunction delocalization with weak interchain π-π stacking as proven by angle-resolved photoemission spectroscopy (ARPES) and grazing incidence wide-angle X-ray scattering (GIWAXS) experiments (2). The measured effective mass is strikingly small, m*≈0.106mₑ (significantly smaller than in silicon), and the orientational order parameter approaches unity in thin films of PCDTPT aligned parallel to the nano-grooves (2).

Despite successes in achieving high charge carrier mobilities, one or more of the inventors of the present invention have found, however, that copolymers containing CDT and BT structural units exhibit relatively high-lying highest occupied molecular orbital (HOMO) levels (−5.0±0.2 eV) (34); not an ideal situation for long-term air stability (below −5.27 eV) (35). For structures containing the more electron withdrawing PT fragments, the basic nature of the PT heterocycle can de-stabilize relevant electronic properties when exposed to air or acidic surfaces (7, 36). As a result, FETs fabricated from PCDTPT produced unreliable device properties (causing variable threshold voltage and mobility) (7). The development of stable semiconducting polymers with high mobility is essential for the growth of “plastic” electronics. Based on the above concerns, one or more embodiments of the present invention sought to design D-A copolymers containing CDT in conjunction fluorine-substituted BT derivatives as the acceptor. This approach was anticipated to lower the orbital levels of the resulting polymers and improve stability both in OFET and optoelectronic devices (37).

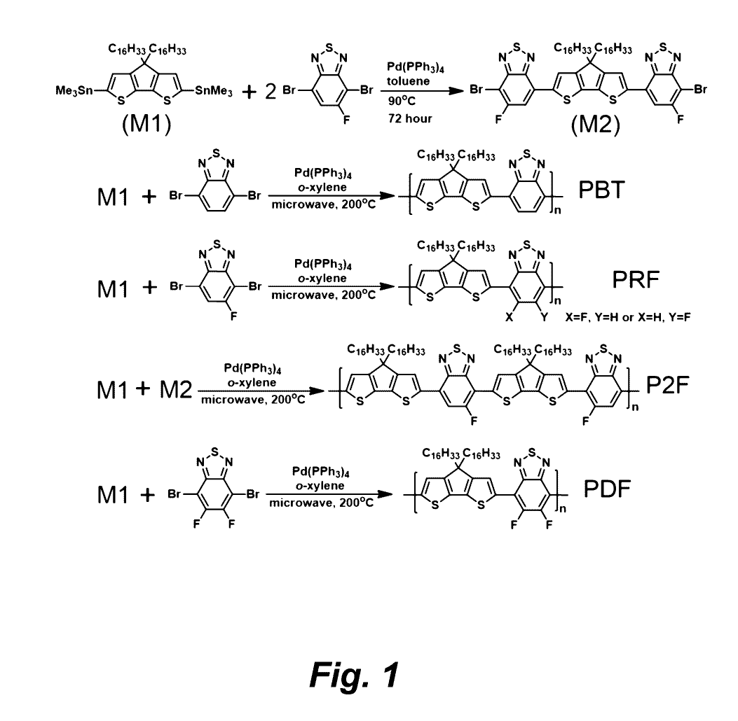

One or more embodiments of the present invention report here a derivative of PCDTBT: poly[5-fluoro-[2,1,3]benzothiadiazole-4,7-diyl(4,4-dihexadecyl-4H-cyclopenta[2, 1-b:3,4-b′]dithiophene-2,6-diyl)-5-fluoro-[2,1,3]benzothiadiazole-7,4-diyl(4,4-dihexadecyl-4H-cyclopenta[2,1-b:3,4-b′]dithiophene-2,6-diyl)] (abbreviation as P2F or PCDTFBT; see FIGS. 1 and 5(a) for the molecular structure). This new polymer, the fluorinated analogue of PBT and PCDTPT, was designed by fluorinating the BT unit in PBT or replacing “N” by “C-F” in the PCDTPT repeat unit to enhance stability. The “C-F” functionality was chosen because (1) the small size of fluorine is suitable for altering “reactive” nitrogen without introducing steric hindrance, (2) electronically, the “C-F” behaves similarly to “N” within the molecular backbone, and (3) the “C-F” is known to be less sensitive to protonation. FETs fabricated from PCDTFBT exhibit more reliable device characteristics and prolonged device lifetime in ambient air.

### First Embodiment: Polymers on Smooth, Planar Substrates

a. Polymer Fabrication

The present disclosure describes synthesis of four polymers with increasing levels of fluorination and structural precision, and then studies their chemical properties, thin films feature, and application in OFETs to investigate the effects of fluorinated BT units. As shown in FIG. 1, the previously reported non-fluorinated reference polymer PBT was prepared via Stille polymerization using (4,4-dihexadecyl-4H-cyclopenta[1,2-b:5,4-b′]dithiophene-2, 6-diyl)bis(trimethylstannane) (M1 in Scheme 1) and 4,7-dibromobenzo[2,1,3]thiadiazole in the presence of catalytic Pd(PPh₃)₄ in anhydrous o-xylene under microwave heating (200° C.). These reaction conditions were used for all other polymer preparations. Single fluorine substitution on BT creates an asymmetric structure and raises the issue of needing to achieve a regioregular backbone for maximizing order within the chain, and ultimately between chains in the solid state (38). Accordingly, equimolar quantities of M1 and 4,7-dibromo-5-fluorobenzo[2,1,3]thiadizaole were reacted directly, ultimately producing a regiorandom polymer referred to in FIG. 1 as PRF. To synthesize the regioregular polymer (P2F), in which the fluorine atoms in alternating structural units point toward the same CDT unit, the symmetric monomer, M2 in FIG. 1, was first prepared by fine control of the Stille reaction temperature and the ratio of M1 and dibromide (36(a)), then carried out the polymerization with M1 and M2. Polymer PDF, with difluorinated BT fragments, was obtained by the polymerization of M1 and 4,7-dibromo-5,6-difluorobenzo[2,1,3]thiadiazole. The molecular weight influence was also considered, particularly in view of subsequent comparisons of physical properties (29(d), 32, 39). The monomer ratio was varied and the Soxhlet extraction purification procedure was optimized by using different solvents. Synthetic details are provided in the Supporting Information (SI) (49). These efforts provided molecular weights in the range of 50-70 kDa for each polymer.

b. Polymer Characterization

With these four polymers in hand, the UV-vis absorption, energy levels, OFET device performance, and film organization and morphologies were investigated with the goal of obtaining insight into the effect of fluorine substitution.

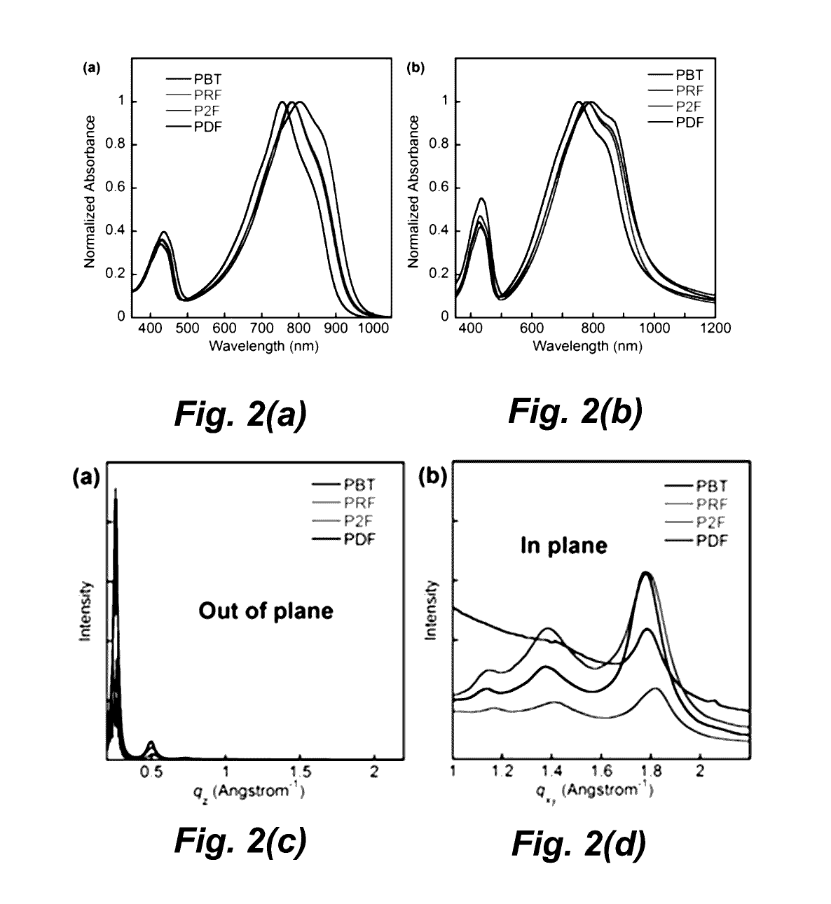

UV-vis absorption was used to examine optical transitions. Solution absorption measurements were carried out in chlorobenzene solvent. As shown in FIG. 2(a), the four polymers show peaks near 430 nm assigned to π-π* transitions. Peaks in the near-IR and IR regions are attributed to intramolecular charge transfer (ICT) excitations.⁷ By examination of the absorption maxima and onsets, one observes that PBT is the most red-shifted, while the di-fluorinated polymer PDF is the most blue-shifted, see Table 1 for a summary of relevant data. The excitation profiles of the two mono-substituted polymers PRF and P2F lie between those of PBT and PDF and are almost identical to each other, with their maximum peaks at 780 nm and 782 nm, respectively.

TABLE 1
Summary of absorption characteristics and orbital energy levels.
λₛₒₗ and λ_{film} refer to absorption peak values in chlorobenzene and
in the thin film, respectively; E_{g}^{opt} is the optical band-gap determined by
film absorption onset; E_{HOMO} and E_{LUMO} are the energy levels from
CV measurements and optical band-gaps.

| | λₛₒₗ | λ_{film} | E_{g}^{opt} | E_{HOMO} | E_{LUMO} |
|---|---|---|---|---|---|
| Polymer | (nm) | (nm) | (eV) | (eV) | (eV) |
| PBT | 436, | 436, | 1.25 | −4.80 | −3.55 |
| | 803 | 793 | | | |
| PRF | 431, | 431, | 1.27 | −5.05 | −3.78 |
| | 780 | 778 | | | |
| P2F | 432, | 431, | 1.25 | −5.03 | −3.78 |
| | 782 | 781 | | | |
| PDF | 427, | 427, | 1.30 | −5.19 | −3.89 |
| | 756 | 755 | | | |

Thin films were prepared by spin-casting from the corresponding chlorobenzene solution and the absorption spectra were measured. As shown in FIG. 2(b) and Table 1, the maxima of the ICT peaks remain largely unchanged, relative to solution. However, one observes a larger contribution from the low energy shoulder, leading to substantial differences in the absorption onsets. The optical band gaps are determined by corresponding thin film absorption onsets, which provide band-gaps of 1.25 eV, 1.27 eV, 1.25 eV and 1.30 eV for PBT, PRF, P2F and PDF respectively. It is interesting to note that the regiorandom (PRF) and regioregular (P2F) versions of the conjugated polymer containing F-BT are nearly identical. However, as demonstrated below, these two materials have very different charge transport characteristics.

Cyclic voltammetry was used to estimate HOMO energy levels by measuring the oxidation potential onsets (40). As shown in Figure S3 in the SI (49), the HOMO level of PBT is −4.80 eV. After mono fluorine substitution, the HOMO levels decrease, with PRF and P2F displaying HOMO levels about −5.05 eV and −5.03 eV respectively. When two fluorine atoms are introduced to the BT unit, the HOMO level decreases further to −5.19 eV. These results highlight the influence of fluorine substitution, which reduces the HOMO levels by as much as 0.39 eV. From a practical perspective the lower HOMO value suggests that, among the polymers studied here, PDF should have the best air-stability in OFET applications (35(a)). Lowest unoccupied molecular orbital (LUMO) energy levels were calculated by adding the optical band-gaps to the HOMO levels. As shown in Table 1, the LUMO levels also decrease with increasing fluorine substitution, in agreement with the stronger electron deficient nature of FBT and DFBT units relative to BT. It is interesting to note that the stabilization of HOMO and LUMO levels by F substitution is similar, which may be surprising in view of the A units greater participation in determining the LUMO levels (41).

Grazing-incidence wide-angle X-ray scattering (GIWAXS) was used to investigate thin film organization (48). The 2D diffraction images are provided in the SI Figure S4-S7 (49), and the line-cut profiles are shown in FIG. 2(c) and FIG. 2(d). In the out of plane direction, there is a strong peak around 0.25 Å⁻¹. A peak around 0.5 Å⁻¹ corresponding to the 2^{nd} order for all polymers, is assigned to alkyl chain stacking features. The alkyl chain stacking distances of all polymers are almost identical at about 2.4 nm, consistent in that they all contain similar hexyldecyl solubilizing unit and suggesting that all polymers share similar lattice organizations. There is no observable peak in the region of 1.0-2.0 Å⁻¹. In the in-plane direction, there is a strong peak around 1.8 Å⁻¹ for all polymers, which is assigned to π-π stacking. Again, the π-π distances are nearly identical (0.35 nm). These features indicate that these polymers present edge-on orientation relative to the substrate plane and also indicate that fluorine substitution in this general backbone framework does not change the crystallite organizations under the film processing conditions disclosed here.

c. OFET Device Characterization

Bottom contact, bottom gate OFETs were fabricated using devices with the following architecture: polymer/Au/SAM/SiO₂/Si (doped). Decyltrichlorosilane (DTS) was used as the self-assembled monolayer on the silicon oxide substrate. Thin films were prepared via doctor-blading (42) and the complete details are provided in the SI (49). Table 2 provides average and maximum mobilites, as determined under nitrogen inside a glovebox by examination of the saturation current regime, together with the corresponding on/off ratios. Average mobilites were calculated from 8 devices.

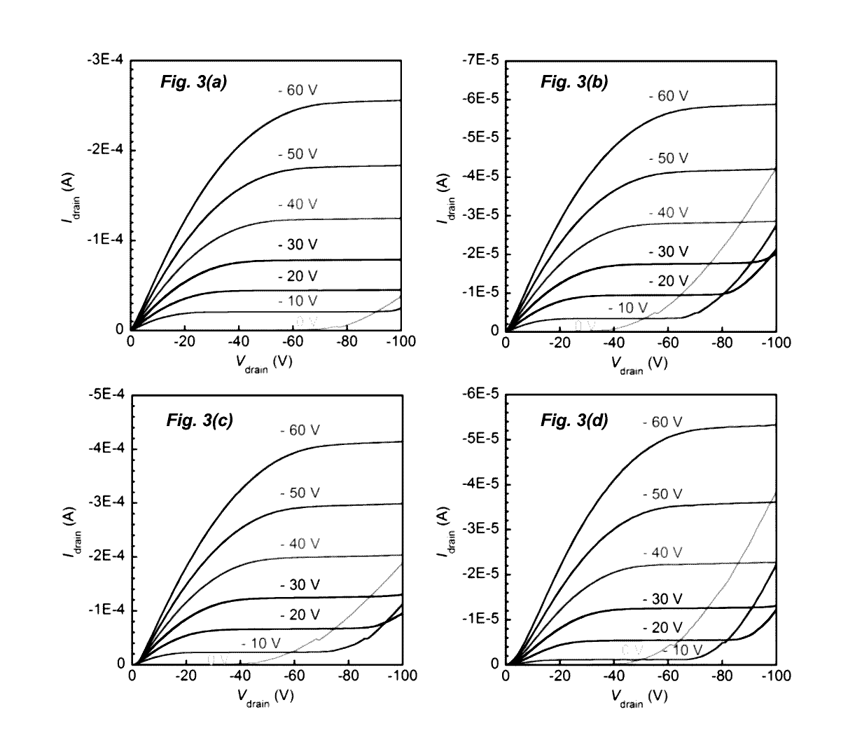

Typical output curves obtained with OFET devices are provided in FIGS. 3(a)-3(d). At high V_{g} (−30-−60V), I_{drain} is saturated when V_{drain} is greater than −70 V. At lower V_{g}, one observes I_{drain} increases with V_{drain} in the range of −40 to −100 V. This feature suggests injection of electrons and therefore an ambipolar nature of the devices.¹⁶ Comparison of FIG. 2(a) vs. 2(d) shows that when the hydrogen atoms are substituted with fluorine atoms, the ambipolar characteristics are more pronounced. One possible reason is that the lower LUMO levels are decreased as more fluorine substitutions have been introduced and that more electron-withdrawing groups can further stable the negative charges that electron transport would improve.¹⁷ The transfer curves are shown in SI Figure S10 (49). The I_{drain}^{1/2} vs. V_{g} curves show nearly-ideal single slope characteristics (45).

TABLE 2
Polymer OFET highest and average mobilities.

| | Mₙ | | Mobility | | | Vₜₕ |
|---|---|---|---|---|---|---|
| Polymer | (kDa) | PDI | cm²V⁻¹s⁻¹ | | On/off | (V) |
| PBT | 68 | 3.6 | 1.4 | (1.1 ± 0.1) | 6.3 × 10² | 10.1 |
| PRF | 53 | 3.3 | 0.4 | (0.3) | 5.5 × 10 | 16.4 |
| P2F | 62 | 3.4 | 1.2 | (0.9 ± 0.2) | 5.5 × 10 | 14.6 |
| PDF | 67 | 4.1 | 0.3 | (0.3) | 2.8 × 10 | 9.6 |

Hole mobilities determined through measurements of OFETs containing different semiconductor polymers are summarized in Table 2. These data indicate that the polymer PBT, at least under these experimental conditions, shows a maximum mobility of 1.4 cm²V⁻¹ s⁻¹. The regiorandom polymer PRF obtains a maximum mobility of 0.4 cm²V⁻¹ s⁻¹, while its regioregular countpart P2F obtains a maximum mobility of 1.2 cm²V⁻¹ s⁻¹. The molecule weight (53 kDa) for the PRF is slightly lower than the other three polymers (60-70 kDa). To verify the molecule weight influence on the mobility, a higher molecular weight batch of PRF was synthesized having a M of 128 kDa and a PDI of 4.4. However, the higher molecule weight batch exhibits a maximum mobility of 0.3 cm²V⁻¹ s⁻¹ (See SI Table-S3 (49)). Therefore, there seems to be no strong molecular weight influence on the performance for PRF at least within the range of the molecular weights investigated in these studies. When comparing PRF and P2F, which have similar chemical structures and absorption profiles, but differ with respect to the structural precision of the backbone, the regioregular polymer (avg. 0.9±0.2 cm²V⁻¹ s⁻¹) exhibits substantially improved performance than the regiorandom counterpart (avg. 0.3 cm²V⁻¹ s⁻¹). The di-fluorinated PDF obtains the lowest mobility, of about 0.3 cm²V⁻¹ s⁻¹ for both the maximum and average mobility. It is interesting since the fluorine substitution could enhance the packing and crystallinity, and in the past, DFBT has been widely reported as a better acceptor unit relative to the BT both in OFET and OPV devices (46), but here seems not the case (47).

Atomic force microscopy (AFM) was used to investigate the surface topographic features of devices, as a function of fluorine substitution. Height images are shown in the SI Figure S3 (49). There is no clear alignment in any of them in agreement with the result that their mobilities are not dependent on the blading direction. All films form continuous polymer domains. It seems there is no obvious difference in the film topography that could support the mobility difference in the device.

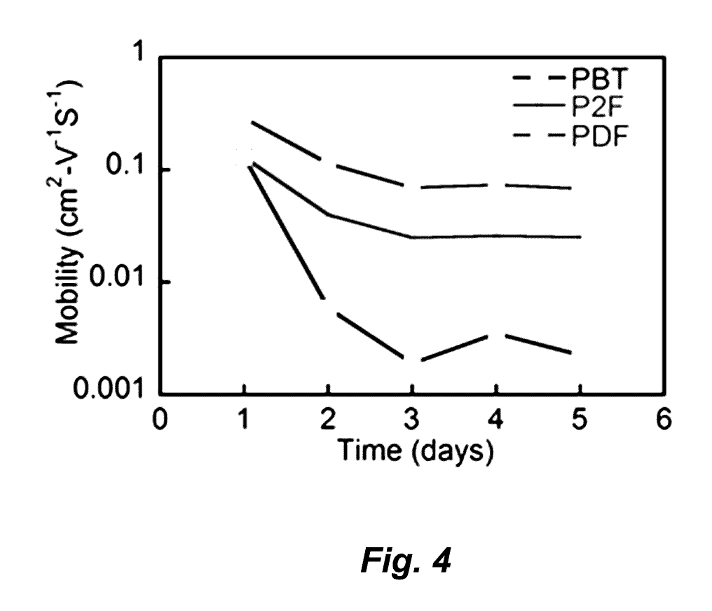

The air stability of PBT, P2F and PDF OFET devices were investigated to verify the benefit of lowering the HOMO levels as a function of fluorine substitutions. Their OFET device performance was measured in ambient conditions after exposure in air for one day and five days, respectively. Their transfer curves are provided in the SI Figure S11 (49), and their mobilities as a function of time are shown in FIG. 4. It is very obvious that the device with PBT is very instable in the air as the mobility decreased to 0.002 cm²V⁻¹ s⁻¹ after 5 days, which is in agreement with the previous report (32(a)). After 5 days, mobility of the mono-fluorinated polymer P2F decreased to 0.03 cm²V⁻¹ s⁻¹ and mobility of the di-fluorinated polymer PDF reduced to 0.07 cm²V⁻¹ s⁻¹. The higher mobility of PDF in air addressed the importance of low-lying HOMO level for OFET applications.

The above results show the present disclosure has developed three novel low band-gap polymers for OFET applications. Fluorine substitution was shown to significantly lower the energy levels. Regioregularity was once again demonstrated as an important design strategy since the mobility of P2F is improved when compared to PRF. However, there appears to be no influence of the molecular structure on the alkyl chain or π-π stacking distance. This is really a subtle feature. It is interesting that the regioregular mono-fluorinated P2F exhibits a similar mobility but the di-fluorinated PDF displayed a lower mobility relative to the non-fluorinated PBT polymer. Nevertheless, PDF exhibited superior advantages in the air stable OFET device applications relative to PBT and P2F as it displayed remarkably deeper HOMO levels.

### Second Embodiment: Polymers on Grooved Substrates with Alignment

a. Polymer Fabrication

Preparation of PCDTFBT (P2F) in this embodiment uses the same technique invented by the inventors and described in the first embodiment described above in FIG. 1. The molecular weights of PCDTPT and PCDTFBT used in this embodiment are both approximately 50 kDa (see supplementary materials), which enables the high degree of chain alignment and associated high mobility along the nano-grooves in the substrate (5). More complete details on the synthesis, characterization and processing of PCDTFBT can be found in the Supplementary Information/methods section (49,50).

b. Film Characterization

(i) Absorption

The UV-Vis-NIR absorption spectra of PCDTPT and PCDTFBT thin films were obtained by using an OLIS 14 UV/VIS/NIR spectrophotometer (On-Line Instrument Systems, Inc.). The samples were prepared by spin casting PCDTPT and PCDTFBT from chlorobenzene solutions (5 mg mL⁻¹) at 600 rpm for 60 s on pre-cleaned quartz substrates.

The measured thicknesses of both PCDTPT and PCDTFBT thin films, −70 nm, were used for estimation of absorption coefficients.

The PCDTFBT thin films exhibit a relatively small optical bandgap (E_{g}≈1.15 eV), though slightly higher than that of a PCDTPT film (E_{g}≈1.02 eV), as shown in FIG. 5(b). These E_{g} values were obtained by plotting the ultraviolet-visible-near infrared (UV-Vis-NIR) absorption spectra using the following equation, [ωα(ω)]^{1/2}=B (ω−E_{g}), where h is the Planck constant, ω is the angular frequency, a is the absorption coefficient, and B is a constant (9). In the (αω)^{1/2} versus ω spectra (inset of FIG. 5(b)), E_{g} values were determined by extrapolating the linear regime of the curves to (αω)^{1/2}=0 (dashed lines). The highest occupied molecular orbital (HOMO) level was estimated to be −5.0 eV, determined by cyclic voltammetry measurements (Fig. S3 in the supplementary information (SI) (50)).

(ii) X-Ray Photoelectron Spectroscopy (XPS)

XPS measurement: The PCDTPT and PCDTFBT thin films were prepared by sandwich casting on pre-cleaned Au substrates in a nitrogen-filled glove box. While inside the glovebox, the samples were mounted and sealed into a capped stainless steel sample holder. The capped holder was then transferred into the XPS antechamber and the cap was removed from the holder after a preliminary vacuum of 1×10⁻⁵ Torr had been achieved. The XPS results were obtained using a Kratos Axis Ultra XPS system (Kratos Analytical Ltd.) at a base pressure of 1×10⁻⁸ Torr using monochromatized Al Kα X-ray photons (hv=1486.6 eV). High-resolution XPS spectra (N is) were obtained at constant pass energy of 40 eV and a step size of 0.1 eV, while survey XPS spectra were taken at pass energy of 160 eV with a step size of 0.5 eV. Data analysis was carried out with CasaXPS software.

The environmentally stable molecular structure of PCDTFBT was confirmed by X-ray photoelectron spectroscopy (XPS) measurements. While ¹H nuclear magnetic resonance (NMR) data prove the fluorinated molecular structure of PCDTFBT (Fig. S1 in the SI (50)), XPS measurements not only confirm the existence of fluorine in the molecular repeat unit of PCDTFBT (Fig. S4 in the SI (50)) but enable clear comparison of N is core levels between PCDTPT and PCDTFBT thin films as shown in FIG. 5(c). The XPS data for a PCDTPT thin film exhibits a broad spectrum containing a peak centered at 401.0 eV (dark grey), which originates from “oxidized” nitrogen (10), consistent with the previous result (7) found by inventors of the present invention. By contrast, PCDTFBT thin film produced unimodal N is core level spectrum centered at 399.9 eV, which originates from the nitrogen in the thiadiazole unit (11). Since previous results (by inventors of the present invention) demonstrate that “oxidized” nitrogen in the pyridyl unit is responsible for the unstable FET properties of PCDTPT (7), the XPS data imply that PCDTFBT should lead to more reliable device characteristics.

(iii) GIWAXS

The samples were prepared onto the Si/n-PVP and Si/n-PVP/SiO₂ (2 nm) substrates using the sandwich casting system. GIWAXS measurements were performed at beamline 11-3 at the Stanford Synchrotron Radiation Lightsource (SSRL) with an X-ray wavelength of 0.9752 Å, at a 400 mm sample to detector distance. Samples were scanned for 300 s in a He environment at an incident angle of 0.10°. The measurements were calibrated using a LaB6 standard. The CCL of π-π stacking for aligned PCDTPT and PCDTFBT were estimated by using fitted GIWAXS line profiles (π-π) and Scherrer equation, CCL=2π/FWHM, where FWHM is the full width at half maximum (1).

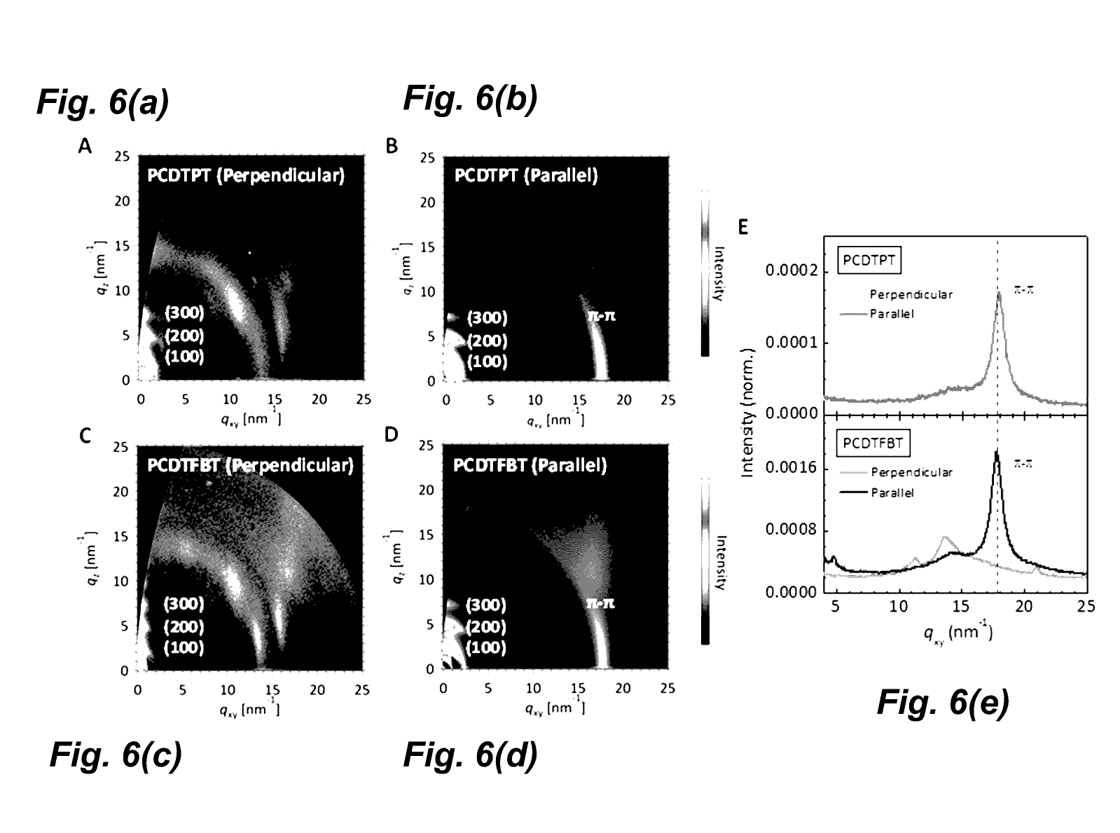

The high crystallinity and associated anisotropy essential for achieving the high mobility of aligned PCDTFBT thin films parallel to the nano-grooves in the substrate were confirmed by GIWAXS experiments. FIGS. 6(a)-6(d) show 2D GIWAXS patterns for PCDTPT and PCDTFBT thin films prepared on nano-grooved silicon substrates in the sandwich casting system (6), where the incident beam is perpendicular or parallel to nano-grooves (henceforth referred to as perpendicular and parallel GIWAXS patterns, respectively). The observed diffraction pattern for PCDTPT is consistent with previous reports (2, 6, 12, 13). The strong “out-of-plane” lamellar alkyl stacking (h00) reflections and the “in-plane” π-π reflection at q≈17.8 nm⁻¹ indicate that the crystallites have a preferential “edge-on” orientation, where q is the scattering vector. Compared with the “in-plane” perpendicular GIWAXS pattern shown in FIG. 6(a), the well-defined “in-plane” π-π reflection in the parallel GIWAXS pattern indicates an orientational order parameter approaching unity (FIG. 6(b)). Similar to the PCDTPT thin films, an aligned PCDTFBT thin film shows uniaxial alignment along and within the nano-grooves and high anisotropy (FIGS. 6(c) and 6(d)). The chain alignment and associated π-π stacking for both materials can be clearly seen through comparison of the normalized line profiles along the q_{xy} (in-plane) direction as displayed in FIG. 6(e). The inventors of the present invention emphasize that the π-π packing distance, d_{π-π}≈0.35 nm, is almost identical for the two polymers, indicating that no steric hindrance is induced by fluorination. The crystalline correlation length (CCL) of π-π stacking is approximately 4.5 nm for both aligned thin films, consistent with the previous result (5).

(iv) Ultraviolet Photoelectron Spectroscopy (UPS)

UPS measurements were carried out using a Kratos Axis Ultra UPS system (Kratos Analytical Ltd.) at a base pressure of 1×10⁻⁸ Torr using the He I source (hv=21.2 eV). The samples were prepared by electron beam deposition of Au (50 nm) and Au/Ni (50/10 nm) onto glass substrates, and were ultraviolet/ozone-treated for 10 min. While inside the glovebox, the samples were mounted and sealed into a capped stainless steel sample holder. The capped holder was then transferred into the UPS antechamber and the cap was removed from the holder after a preliminary vacuum of 1×10⁻⁵ Torr had been achieved. During UPS measurements, a sample bias of −9 V was used. The UPS results were obtained at constant pass energy of 20 eV with a step size of 0.025 eV. Data analysis was carried out with CasaXPS software.

(v) GPC Measurement

GPC was performed in chloroform (CHCl₃) on a Waters Breeze2 Separation Module equipped with a Waters 2414 Refractive Index Detector. Polystyrene standards were used to calibrate the system. The molecular weight (Mₙ) was estimated to be 46 KDa and 50 KDa for PCDTBT and PCDTFBT, respectively. The polydispersity index (PDI) was estimated to be ˜3 for both polymers.

(vi) CV Measurements

CV measurement was conducted using a standard three electrode configuration under an argon atmosphere. A three electrode cell equipped with a glassy carbon as a working electrode, an Ag wire as a reference electrode, and a Pt wire as a counter electrode. The measurements were performed in absolute acetonitrile with tetrabutylammonium hexafluorophosphate (0.1 M) as the supporting electrolyte at a scan rate of 50-100 mV s⁻¹ (Figure S3 (50)).

c. OFET Characterization

The OFETs were fabricated onto n-SiO₂ substrates prepared by rubbing a n++Si (500 μm)/SiO₂ (300 nm) substrate (International Wafer Services Co.) with a diamond lapping disc with particle sizes of 100 nm (Allied High Tech Products Inc.) as described in detail in the previous reports (1, 2). The Ni (5 nm)/Au (50 nm)/Ni (10 nm) source and drain electrodes (W/L=1,000/200 m) were patterned on the dielectrics through a conventional photolithography process. All metal electrodes were deposited by electron beam evaporation at 7×10⁷ Torr. After ultraviolet/ozone treatment of pre-cleaned n-SiO₂ substrates for 10 min, the substrates were passivated with the n-decyltrichlorosilane (Gelest Inc.) in toluene solution (1% by volume) at room temperature for 17 h in a nitrogen-filled glove box. The PCDTPT and PCDTFBT (both materials were purchased from 1-Material Inc., but wherein both polymers were synthesized according to the procedures invented by one or more of the inventors and described in FIG. 1 and the associated text, and reference (3)) were then cast from a chlorobenzene solution (0.25 mg mL⁻¹) for approximately 5 h through the sandwich casting in a nitrogen-filled glove box (2).

The devices were then cured at 200° C. for 2 min prior to measurements, and were tested using a probe station (Signatone Co.) in a nitrogen-filled glove box. For mobility measurement at various annealing temperatures, devices were mounted on a hot stage (STC 200; Instec Inc.) for 1 min at each temperature. Data were collected by a Keithley 4200 system.

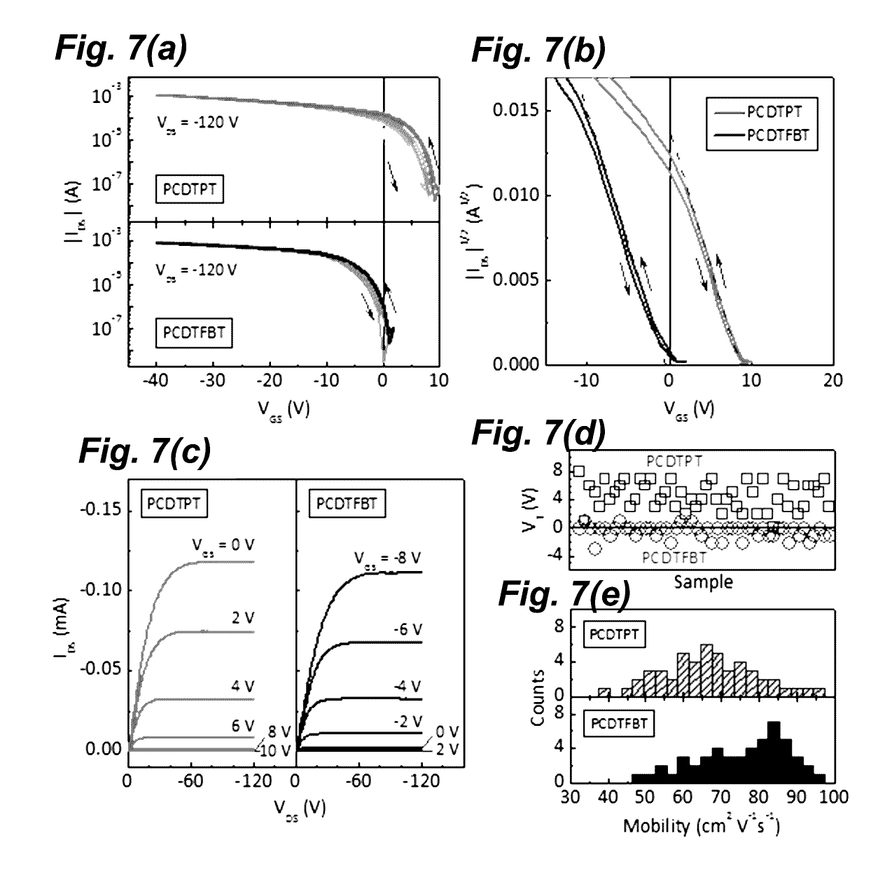

To investigate the charge transport and reliability of PCDTFBT, one or more embodiments of the present invention fabricated 50 FETs with aligned PCDTFBT thin films as the electronically active semiconductor in the channel. The device properties were analyzed and compared with those of 50 reference devices fabricated with aligned PCDTPT thin films (FIGS. 7(a)-7(c)). FETs were fabricated as described above by casting PCDTPT and PCDTFBT thin films onto nano-grooved SiO₂/n++Si substrates with pre-patterned source and drain electrodes in the sandwich casting system to complete the bottom gate bottom contact geometry (6). The field-effect mobilities can be extracted in the saturation regime from the following equation,

I_{DS}=(W/2L)Cμ(V_{GS}−V_{T})² (1)

where, I_{DS} is the source-drain current, W is the channel width, L is the channel length, C is the gate dielectric capacitance per unit area, is the saturation carrier mobility, V_{GS} is the gate-source voltage, and V_{T} is the threshold voltage. The inventors of the present invention note that measured saturation mobility is V_{GS} dependent with higher mobility obtained in the low V_{GS} regime as shown in FIG. 7(b) (5-7). One or more embodiments focus on the high mobility regime (i.e. low V_{GS} regime: V_{GS}−V_{T}≦−10 V) useful in digital electronics.

The representative transfer curves of 5 FETs fabricated from PCDTPT or PCDTFBT as the FET channel are displayed in FIG. 7(a). The transfer curves and output curves of one of the best devices with PCDTPT and PCDTFBT (highlighted in dark grey and red, respectively, in FIG. 7(a)) are displayed in FIGS. 7(b) & 7(c), respectively. Saturation and pinch-off are observed in the output curves of both devices. The highest saturation hole mobility of aligned PCDTFBT is approximately 97 cm²/V-s, similar to that of PCDTPT, ≈96 cm²/V-s. Although the highest mobilities are comparable for the two materials, one finds that FETs with PCDTFBT produced more stable transfer curves (showing V_{T} values at around 0 V), compared with those of PCDTPT counterparts (see FIG. 7(a)). Since variable transfer curves (causing variable V_{T} values) of PCDTPT devices originate from impurity doping of PCDTPT thin films (7), the inventors of the present invention associate the enhanced reliability with substitution of fluorine for the reactive nitrogen in the PCDTPT repeat unit.

The enhanced reliability of PCDTFBT can be more clearly seen by comparing V_{T} and mobility values extracted from 50 independent FETs with PCDTPT or PCDTFBT as displayed in FIGS. 7(d) and 7(e), respectively. As shown in FIG. 7(d), V_{T} values of PCDTPT devices are variable (V_{T}≈0 to 8 V), consistent with previous results (4-7). By contrast, most of PCDTFBT devices produced V_{T}≈0 V, as required for proper operation in electronic circuits. The inventors of the present invention note that to obtain reproducible transfer curves, sweeping to large positive V_{GS} (where electron injection into traps degrades the performance) should be avoided. The mobility values of 50 PCDTFBT devices show a somewhat narrower distribution compared with those obtained from the 50 PCDTPT devices (FIG. 7(e)). As a result, PCDTFBT devices yielded the higher average mobility, ≈76 cm²/V-s, compared with that of PCDTPT devices (μ≈65 cm²/V-s).

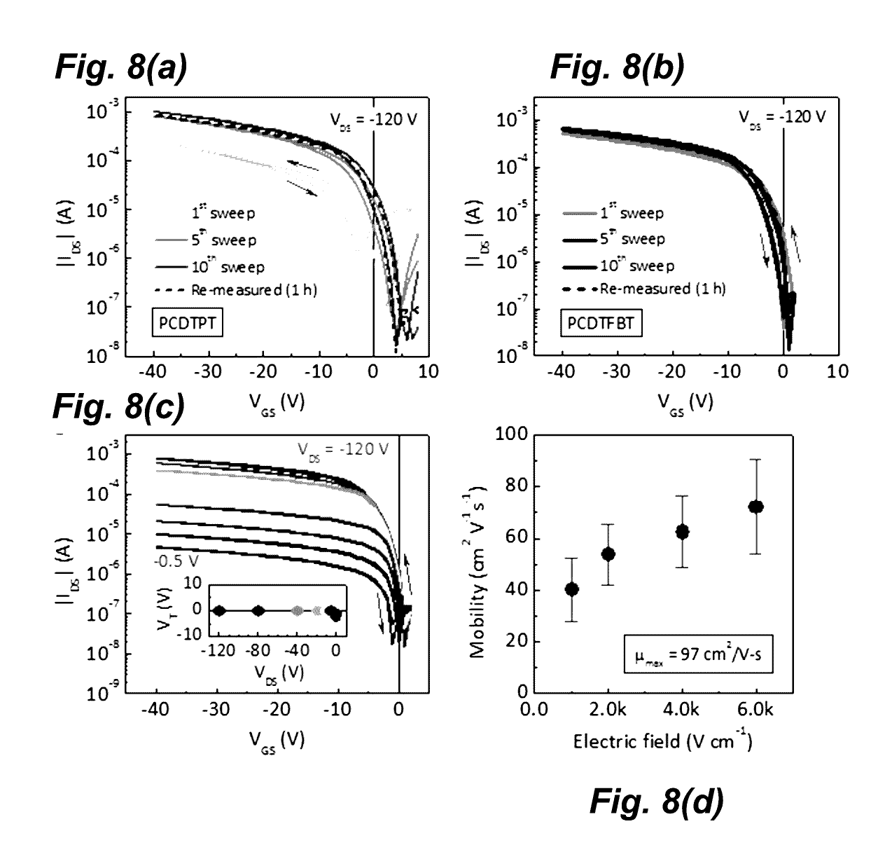

Stable transistor characteristics are essential requirements for practical applications of plastic circuits. The inventors note that the high performance FETs described in the present disclosure are stable under continuous operating condition. To minimize possible electron injection into traps that causes electrical instability, one or more embodiments of the present invention introduced oxidized nickel electrodes as electron-blocking layers on top of gold source and drain electrodes in the FET configuration. As a result, devices fabricated with oxidized nickel electrodes exhibit stabilized transistor characteristics with less electron injection as displayed in FIGS. 8(a) & 8(b), compared with those of devices without oxidized nickel layers (Fig. S5 in the SI (50)). In addition, the larger work function of oxidized nickel-covered gold electrode, WF≈−5.15 eV, compared with that of pure gold electrode (WF≈−4.93 eV), is thought to enhance hole injection and associated mobility (Fig. S6 in the SI (50)). Although the detailed mechanism for the performance degradation induced by injected electrons is not clear, PCDTFBT shows significantly better operational stability (FIG. 8(b)), even in devices with pure gold electrodes (Fig. S5 in the SI (50)).

The transistor characteristics of devices with aligned PCDTFBT thin films are also stable at various operating voltages. To assess operational stability of PCDTFBT FETs, electric field dependent transconductance measurements for FETs fabricated from PCDTFBT were performed. Transfer curves were taken at varying V_{DS} from −120 V to −0.5 V (FIG. 8(c)) and V_{T} values were extracted from the measured transfer curves as displayed in the inset of FIG. 8(c). The V_{T} values remained at approximately 0 V even at low V_{DS} (linear regime), implying low interfacial trap density.

Strikingly high saturation mobilities approaching 100 cm²/V-s, the highest value for semiconducting polymers reported to date (6, 14-18), were obtained at high V_{DS} (V_{DS}≧−120 V). The implied electric field dependence is a real effect; the extracted average hole mobilities taken at V_{DS}=−20 to −40 V (t≈40-53 cm²/V-s) are still high (FIG. 8(d)). The electric field dependence was also observed for PCDTPT and for other semiconducting polymer systems (19, 20). The inventors associate the electric field dependence with defects and transport barriers in quasi-one dimensional polymer semiconductors.

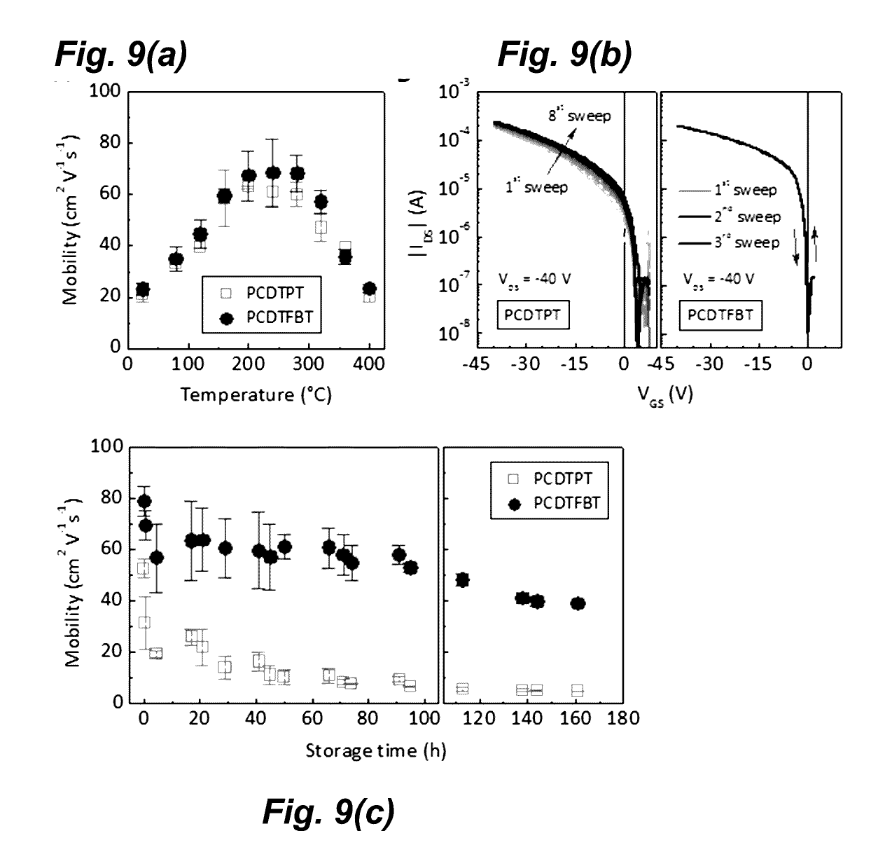

The thermal stability of aligned PCDTFBT thin films was investigated by measuring FET mobilities at various annealing temperatures. FIG. 9(a) displays saturation hole mobilities taken at various annealing temperature, where devices were mounted on a hot stage for 1 min for each annealing process. The highest mobility of PCDTPT was observed following annealing at 200° C., which is consistent with our previous results (5-7). Similarly, the highest mobilities for PCDTFBT were observed at annealing temperature range between 200-280° C. Both materials exhibited similar mobilities after high temperature annealing up to 400° C., showing reduced mobility (≈20 cm²/V-s) due to polymer degradation. However, it is noteworthy that the PCDTFBT device produced stable transistor characteristics following high temperature annealing (Fig. S7 in the SI (50)), whereas the PCDTPT device shows unstable transistor characteristics (FIG. 9(b)).

More importantly, enhanced air-stability for aligned PCDTFBT thin films was observed. FIG. 9(c) displays the mobilities of FETs with aligned PCDTPT and PCDTFBT thin films as a function of storage time in ambient air (22-30° C. and 45-70% RH). The mobility of PCDTPT decreased exponentially, as is typically found for other semiconducting polymers (21-24). By contrast, PCDTFBT devices showed reasonably high mobilities after up to 100 hours (h) of storage in ambient air (the devices were kept in a nitrogen-filled glove box for certain periods indicated by the grey boxes in FIG. 9(c), totaling approximately 50 h). The average saturation mobility of PCDTFBT devices is retained at approximately 40 cm²/V-s (≈50% value of the initial mobility) following a long period (>100 h) in ambient air. Note that the PCDTFBT thin films were directly exposed to ambient air in the bottom-gated FET configuration without any encapsulation layers. Aside from the burn-in loss (<4 h), the high mobilities measured after exposure to ambient air demonstrate that the fluorinated molecular framework leads to remarkably enhanced air-stability. Although it has been known for years that stability of organic molecules can be enhanced by fluorination (25-27), this prolonged air-stability combined with high mobility demonstrates that semiconducting polymers are promising materials for realization of high-performance practical applications.

Through facile fluorination of PCDTPT and PBT, the stable and high-mobility semiconducting polymer, PCDTFBT, has been demonstrated and thoroughly characterized. By demonstrating that aligned PCDTFBT leads to a record high mobility approaching 100 cm²/V-s at higher source-drain operating voltage and that the associated FET characteristics were electrically, thermally, and air-stable, the results presented in the present disclosure provide molecular design guidelines for stable and high-mobility semiconducting polymers for high-performance “plastic” electronics, and demonstrate that semiconducting polymers can compete with their inorganic counterparts in a variety of low-cost electronics applications.

### Process Steps

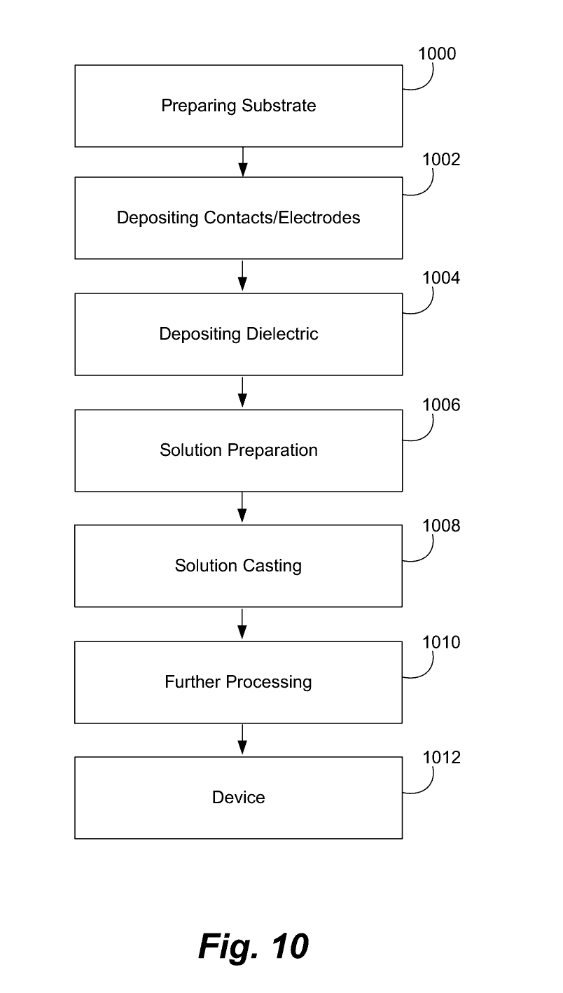

FIG. 10 is a flowchart illustrating a method for fabricating an OFET. The method can comprise the following steps.

Block 1000 represents obtaining/providing and/or preparing a substrate. In one or more embodiments, the substrate comprises a flexible substrate. Examples of a flexible substrate include, but are not limited to, a plastic substrate, a polymer substrate, a metal substrate, or a glass substrate. In one or more embodiments, the flexible substrate is at least one film or foil selected from a polyimide film, a polyether ether ketone (PEEK) film, a polyethylene terephthalate (PET) film, a polyethylene naphthalate (PEN) film, a polytetrafluoroethylene (PTFE) film, a polyester film, a metal foil, a flexible glass film, and a hybrid glass film.

Block 1002 represents optionally forming/depositing contacts or electrodes (e.g., p-type, n-type contacts, or a gate, source, and/or drain contacts) on or above (or as part of) the substrate.

In an OFET embodiment comprising a top gate & bottom contact geometry, source and drain contacts are deposited on the substrate. Examples of the source and drain contacts include, but are not limited to, gold, silver, silver oxide, nickel, nickel oxide (NiOx), molybdenum, and/or molybdenum oxide. In one or more embodiments, the source and drain contacts of the OFET further comprise a metal oxide electron blocking layer, wherein the metal includes, but is not limited to nickel, silver or molybdenum.

In an OFET embodiment comprising a bottom gate geometry, a gate electrode is deposited on the substrate. In one or more embodiments, the gate contact (gate electrode) is a thin metal layer. Examples of the metal layer for the gate include, but are not limited to, an aluminum layer, a copper layer, a silver layer, a silver paste layer, a gold layer or a Ni/Au bilayer. Examples of the gate contact further include, but are not limited to, a thin Indium Tin Oxide (ITO) layer, a thin fluorine doped tin oxide (FTO) layer, a thin graphene layer, a thin graphite layer, or a thin PEDOT:PSS layer. In one or more embodiments, the thickness of the gate electrode is adjusted (e.g., made sufficiently thin) depending on the flexibility requirement.

The gate, source, and drain contacts can be printed, thermal evaporated, or sputtered.

Block 1004 represents optionally depositing a dielectric on the gate electrode, e.g., when fabricating an OFET in a bottom gate configuration. In this example, the dielectric is deposited on the gate contact's surface to form a gate dielectric.

The step can comprise forming a coating (e.g., a dielectric coating) or one or more dielectric layers, on the substrate. The dielectric layers can comprise silicon dioxide, a polymer (e.g., PVP) dielectric layer, a polymerized ionic liquid (PIL), or multiple dielectric layers (e.g., a bilayer dielectric). The dielectric layers can be solution coated on the substrate. A single polymer dielectric layer may be preferred in some embodiments (for easier processing, more flexibility). In one embodiment, the dielectric layers can form a polymer dielectric/SiO₂ bilayer. In another embodiment, the dielectric layers form a polymer dielectric/SiO₂/SAM multilayer with the SiO₂ on the polymer and the alkylsilane or arylsilane Self Assembled Monolayer (SAM) layer on the SiO₂. In another embodiment, the dielectric layers form a SiO₂/SAM bilayer with the alkylsilane or arylsilane SAM layer on the SiO₂. Various functional groups may be attached to the end of the alkyl groups to modify the surface property of the SAM layer.

The thickness of the coating/dielectric (e.g., SiO₂) may be adjusted/selected. For example, the thickness may be adjusted (e.g., made sufficiently thin) depending on the composition of the dielectric layers and the flexibility requirement. For example, in one embodiment, the dielectric layer might not include a polymer dielectric layer and still be flexible.

The dielectric or coating can be structured or patterned to form one or more grooves or structures (such as nanogrooves/nanostructures, e.g., having a depth of 6 nanometers or less and/or a width of 100 nm or less) in the dielectric. The source and drain can be positioned such that a minimum distance between the source contact and drain contact is substantially parallel to the longitudinal axis of the nanogrooves (e.g., a minimum distance between the source contact and drain contact can be substantially parallel to the longitudinal axis of the nanogrooves).

In one or more embodiments, the nanogrooves are formed by nano-imprinting (i.e., the nanogrooves are nanoimprinted into the dielectric or substrate). For example, the step of fabricating the dielectric layers can comprise nano-imprinting a first dielectric layer (e.g., PVP) deposited on the substrate; and depositing a second dielectric layer on the nanoimprinted first dielectric layer, wherein a thickness of the second dielectric layer comprising SiO₂ is adjusted.

Block 1006 represents fabricating or obtaining one or more semiconducting polymers in solution.

In one or more embodiments, each of the semiconducting polymers comprise polymer chains having a backbone including an aromatic ring, the aromatic ring comprising an element (e.g., fluoro functionality) having reduced susceptibility to oxidization as compared to pyridine nitrogen.

In one or more embodiments, the semiconducting polymers have fluoro functionality comprising an acceptor structure including a regioregular fluoro-phenyl unit.

In one or more embodiments, the semiconducting polymer comprises a (e.g., regioregular) conjugated main chain section, the conjugated main chain section having a repeat unit that comprises a compound of the structure:

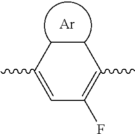

wherein Ar is a substituted or non-substituted aromatic functional group containing one, two, three or more aromatic rings, or Ar is nothing and the valence of the ring comprising fluorine (F) is completed with hydrogen. In one or more embodiments, the ring comprising F is regioregularly arranged along the conjugated main chain section.

In one or more examples, the ring comprising the F has the structure:

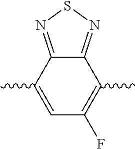

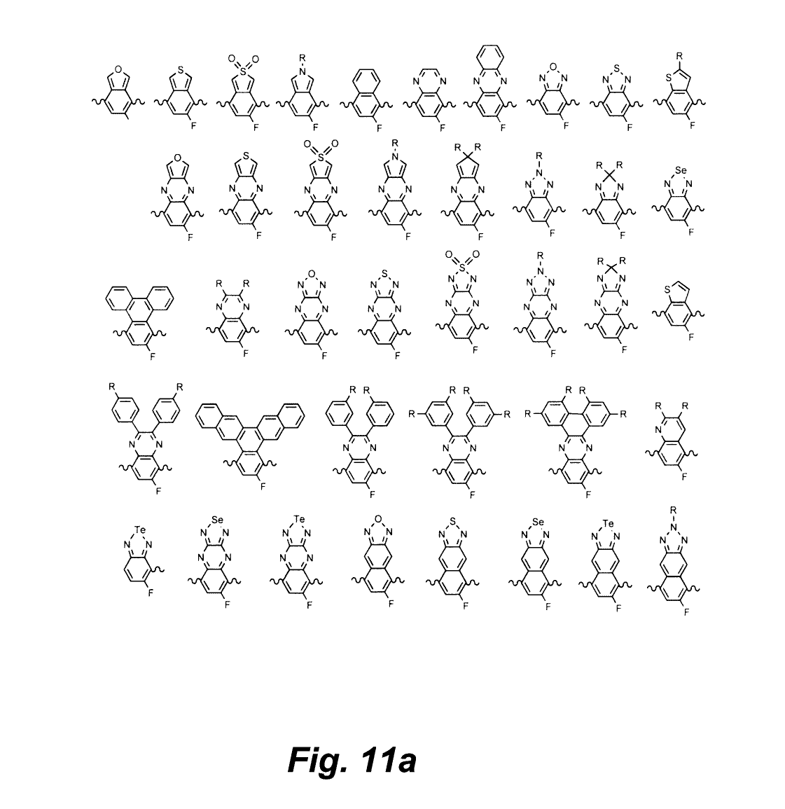

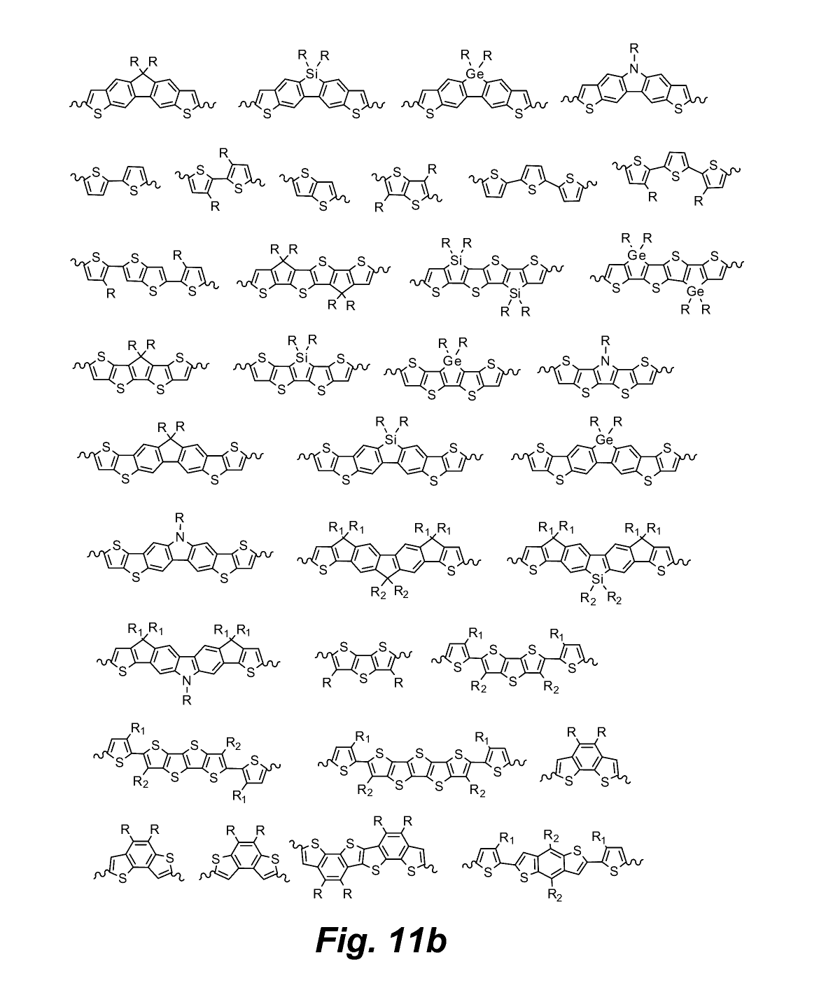

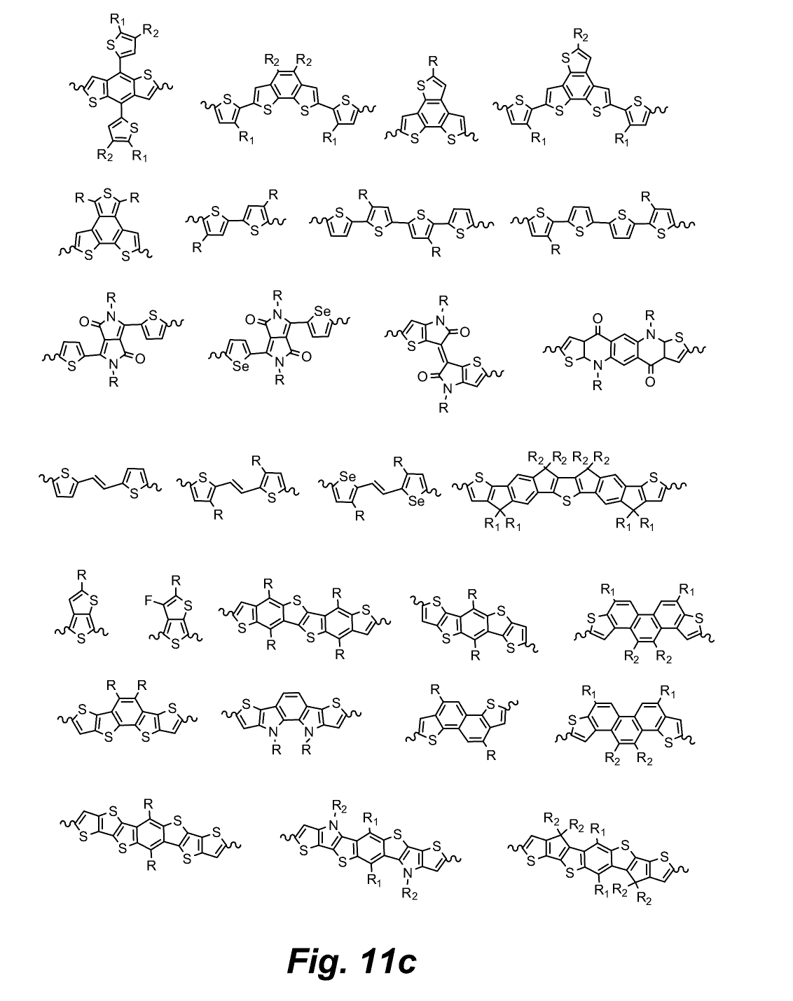

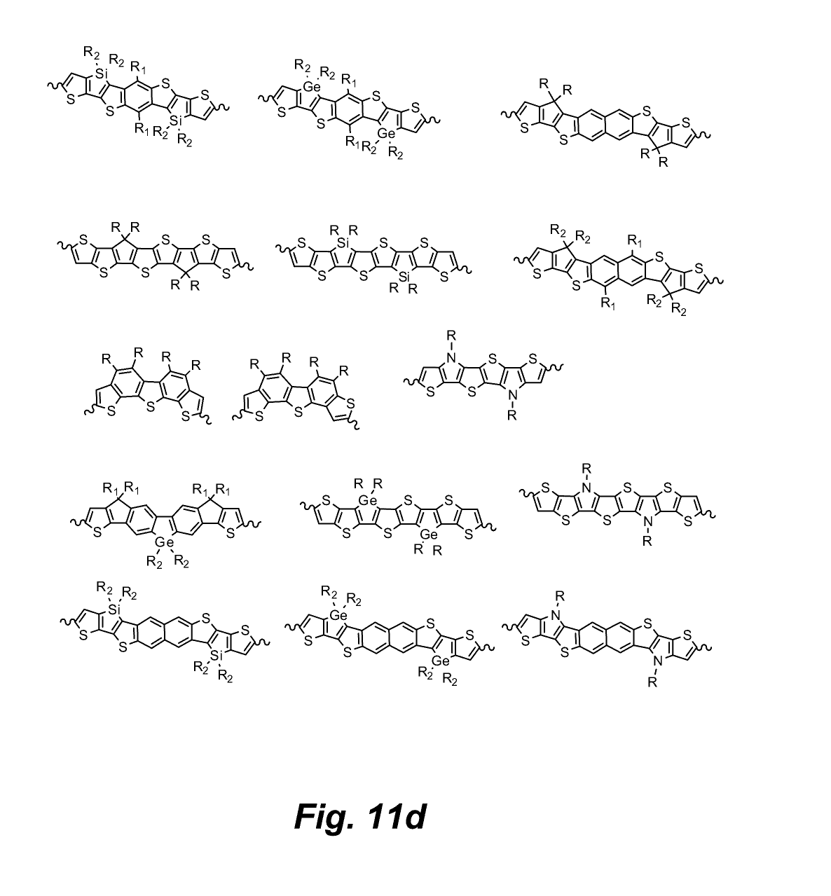

Other examples include those illustrated in FIG. 11a, where each R is independently a substituted or non-substituted alkyl chain, which can be a C₆-C₃₀ substituted or non-substituted alkyl chain, —(CH₂CH₂O)n (n=2˜20), C₆H₅, —CₙF₍₂ₙ₊₁₎ (n=2˜20), —(CH₂)ₙN(CH₃)₃Br (n=2˜20), —(CH₂)ₙN(C₂H₅)₂ (n=2˜20), 2-ethylhexyl, PhCₘH₂ₘ₊₁ (m=1-20), —(CH₂)ₙSi(CₘH₂ₘ₊₁)₃ (m, n=1 to 20), or —(CH₂)ₙSi(OSi(CₘH₂ₘ₊₁)₃)ₓ(CₚH₂ₚ₊₁)_{y} (m, n, p=1 to 20, x+y=3), for example; in some embodiments, the R groups can be the same.

In one or more embodiments, the repeat unit further comprises a dithiophene of the structure:

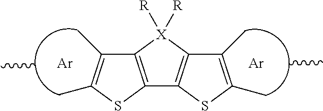

wherein each Ar is independently a substituted or non-substituted aromatic functional group, or each Ar is independently nothing and the valence of its respective thiophene ring is completed with hydrogen, each R is independently hydrogen or a substituted or non-substituted alkyl, aryl, or alkoxy chain, and X is C, Si, Ge, N or P. In some embodiments, the R groups can be the same. In the dithiophene, the R comprising the substituted or non-substituted alkyl, aryl or alkoxy chain can be a C₆-C₃₀ substituted or non-substituted alkyl or alkoxy chain, —(CH₂CH₂O)n (n=2˜20), C₆H₅, —CₙF₍₂ₙ₊₁₎ (n=2˜20), —(CH₂)ₙN(CH₃)₃Br (n=2˜20), 2-ethylhexyl, PhCₘH₂ₘ₊₁ (m=1-20), —(CH₂)ₙN(C₂H₅)₂ (n=2˜20), —(CH₂)ₙSi(CₘH₂ₘ₊₁)₃ (m, n=1 to 20), or —(CH₂)ₙSi(OSi(CₘH₂ₘ₊₁)₃)ₓ(CₚH₂p+1)_{y} (m, n, p=1 to 20, x+y=3).

Examples of dithiophene units include those illustrated in FIGS. 11b-11d of the present disclosure and Table B (FIG. 30B) in U.S. Utility patent application Ser. No. 14/426,467, filed on Mar. 6, 2015, by Hsing-Rong Tseng, Lei Ying, Ben B. Y. Hsu, Christopher J. Takacs, and Guillermo C. Bazan, entitled “FIELD-EFFECT TRANSISTORS BASED ON MACROSCOPICALLY ORIENTED POLYMERS,” Attorney's Docket No. 30794.0514-US-WO (UC REF 2013-030), wherein the definition of R, R1 and R2 in FIGS. 11b-d is the same as the definition for the R groups given above.

In one or more examples, the dithiophene unit comprises:

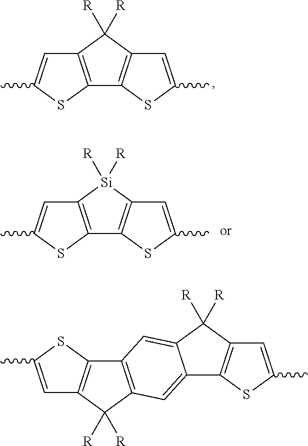

In one or more embodiments, the semiconducting polymer has the structure with repeating units D comprising the dithiophene and repeating units A comprising the ring comprising the fluorine, e.g., [D-A-D-A]ₙ where n is an integer representing the number of repeating units, D is a donor structure, and A is an acceptor structure. In one or more embodiments, the structure has a regioregular conjugated main chain section having 5-150, or more, contiguous repeat units. In some embodiments, the number of repeat units is in the range of 10-40 repeats. The regioregularity of the conjugated main chain section can be 95% or greater, for example.

Thus, in one or more embodiments, the semiconducting polymer is a regioregular semiconducting polymer comprising a repeating unit of the structure:

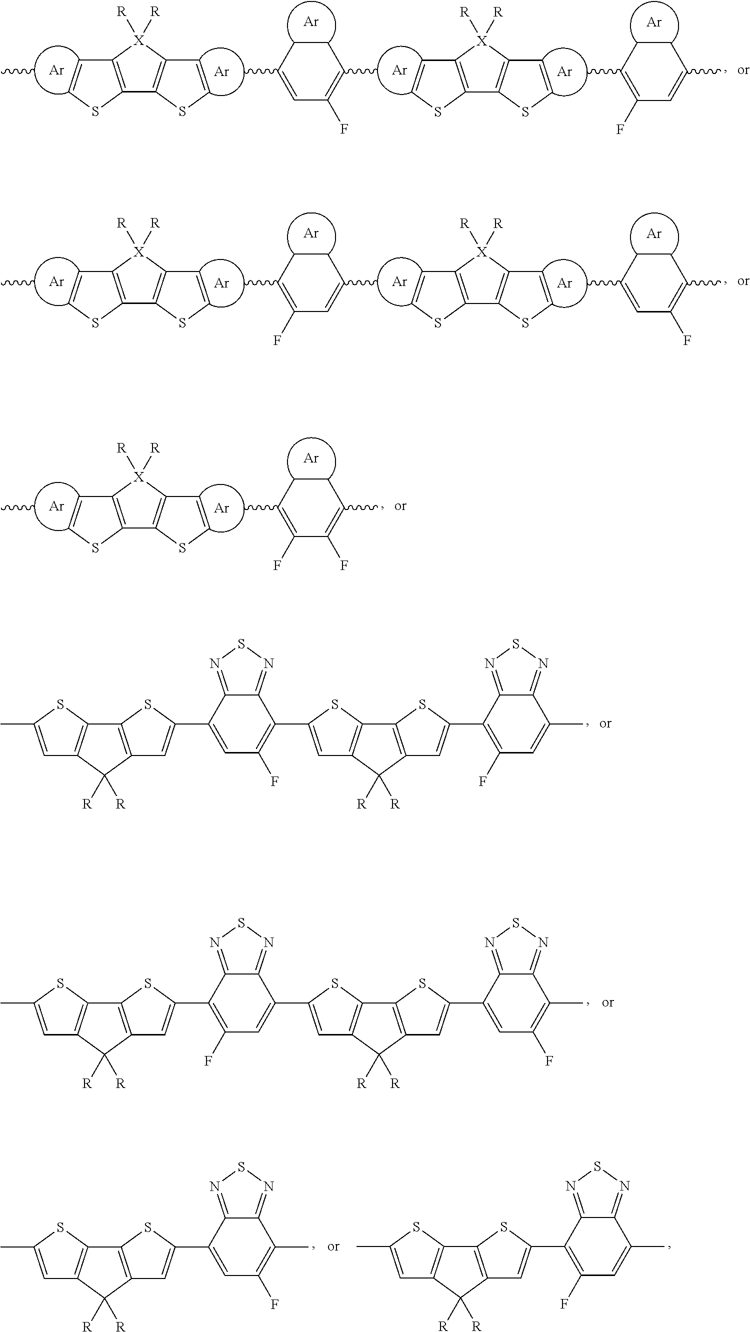

where the ring comprising F is regioregularly arranged along the conjugated main chain section pointing toward the direction shown in the structures above, Ar is a substituted or non-substituted aromatic functional group containing one, two, three or more aromatic rings, or Ar is nothing and the valence of the ring comprising fluorine (F) is completed with hydrogen, the R groups comprising the substituted or non-substituted alkyl, aryl or alkoxy chain can be a C₆-C₃₀ substituted or non-substituted alkyl or alkoxy chain, —(CH₂CH₂O)n (n=2˜20), C₆H₅, —CₙF₍₂ₙ₊₁₎ (n=2˜20), —(CH₂)ₙN(CH₃)₃Br (n=2 20), 2-ethylhexyl, PhCₘH₂ₘ₊₁ (m=1-20), —(CH₂)ₙN(C₂H₅)₂ (n=2 20), —(CH₂)ₙSi(CₘH₂ₘ₊₁)₃ (m, n=1 to 20), or —(CH₂)ₙSi(OSi(CₘH₂ₘ₊₁)₃)ₓ(CₚH₂p+1)_{y} (m, n, p=1 to 20, x+y=3).

For example, the semiconducting polymer can be regioregular poly[5-fluoro-[2,1,3]benzothiadiazole-4,7-diyl(4,4-dihexadecyl-4H-cyclopenta[2,1-b:3,4-b′]dithiophene-2, 6-diyl)-5-fluoro-[2,1,3]benzothiadiazole-7,4-diyl(4,4-dihexadecyl-4H-cyclopenta[2,1-b:3,4-b′]dithiophene-2,6-diyl)] (P2F or PCDTFBT).

Further additives or compositions may be added to the solution, e.g., to form a blend.

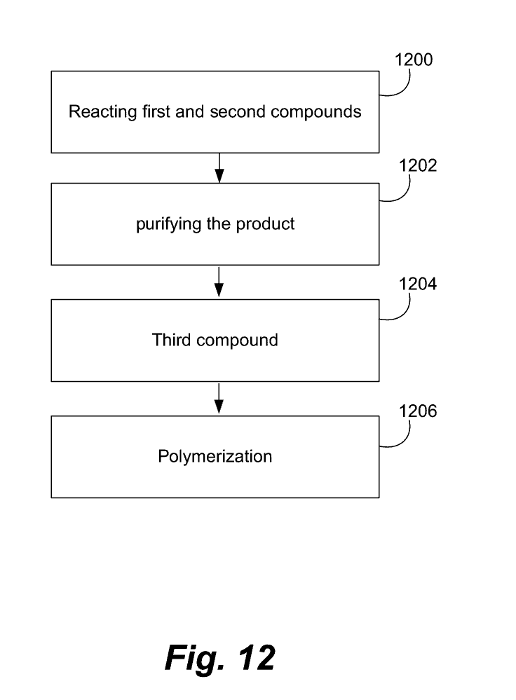

FIG. 12 is a flowchart illustrating a method of preparing the semiconducting polymers.

Block 1200 represents reacting a first compound and second compound in a solution. In one or more embodiments, the first compound has the structure:

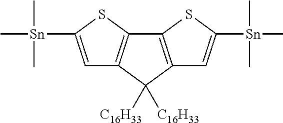

However, in one or more embodiments, the C₁₆H₃₃ are replaced with R as indicated above to achieve the desired R in the semiconducting polymers. In one or more embodiments, the Sn is not required and the first compound is terminated with a proton on either side.

In one embodiment, the second compound has the structure:

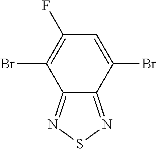 [SMILES: Fc1cc(Br)c2nsnc2c1Br]

In one or more embodiments, the reacting comprises mixing a solution comprising the first compound and the second compound to form a mixture and heating the mixture (e.g., to 90° C.) in an oil bath, obtaining a product.

Block 1202 represents purifying the product in a solvent mixture using chromatography. In one or more embodiments, the solvent mixture comprises chloroform:hexane (with more hexane than chloroform, e.g., 20%-33% chloroform). In one or more embodiments, the chloroform/hexane v/v ratio is ¼, ⅓, or, ½, or between ¼ and ½. Surpisingly and unexpectedly, it was discovered that selection of the proper solvent mixture (more hexane than chloroform) obtained the regioregularity of the third compound (this is unexpected/surprising because a solvent comprising less hexane than chloroform (e.g., hexane:chloroform ratio of 1:3) is used during purification to obtain regioregularity of PCDTPT polymers.

Block 1204 represents the end result of steps 1200-1202, a third compound.

In one or more embodiments, the third compound has the structure:

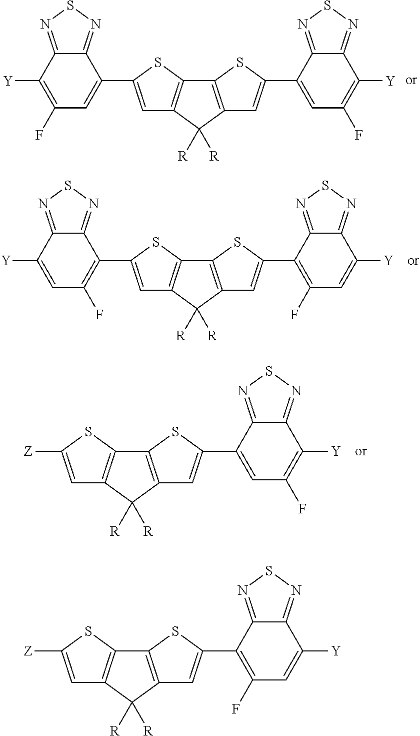

where each Y is bromide, iodide, pseudo-halides or triflate; Z is hydrogen, alkenyl, borate, Sn(Me)₃ or Sn(Bu)₃; each R is independently hydrogen or a substituted or non-substituted alkyl, aryl, or alkoxy chain.

In one or more embodiments, the third compound has the structure:

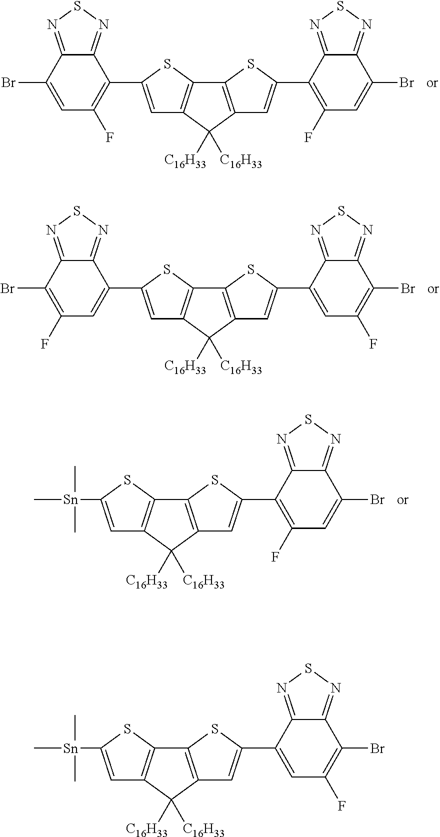

wherein, in one or more embodiments, C₁₆H₃₃ is replaced by R as described herein.

Block 1206 represents polymerizing the third compound to obtain the regioregular semiconducting polymers described above.

Block 1008 represents solution casting/processing the solution comprising the semiconducting polymers, such that the semiconducting polymers are deposited (from the solution) in a film on or above the substrate or on the dielectric. In one or more embodiments, nanogrooves provide nucleation sites for growth of polymer chains within the solution so that one or more of the polymer chains seed and stack within one or more of the nanogrooves.

Solution casting methods include, but are not limited to, inkjet printing, bar coating, spin coating, blade coating, spray coating, roll coating, dip coating, free span coating, dye coating, screen printing, and drop casting.

Block 1010 represents further processing the polymer film cast on the dielectric/substrate. The step can comprise annealing/curing/drying the polymer (or allowing the polymer to dry). The step can comprise depositing source and drain contacts, if necessary.

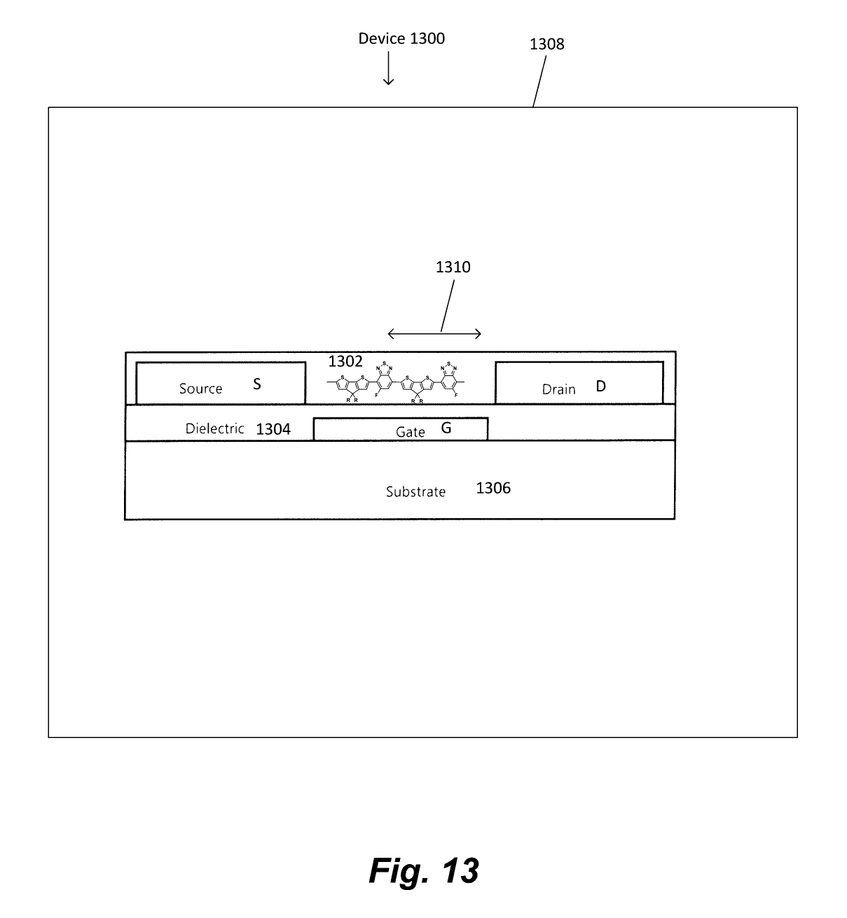

Block 1012 represents the end result, a device 1300. In one or more embodiments, the device 1300 includes one or more OFETs, e.g., as illustrated in FIG. 13. Each OFET comprises a source contact S and a drain contact D to a film comprising the one or more semiconducting polymers 1302; and a gate connection G on a dielectric 1304, wherein the gate connection G applies a field to the one or more semiconducting polymers across the dielectric 1304 to modulate conduction along one or more backbones of the one or more semiconducting polymers in a channel/active region between the source contact S and the drain contact D.

Embodiments of the present invention are not limited to the particular sequence of depositing the source, drain, and gate contacts. For example, OFETs according to one or more embodiments of the present invention can be fabricated in a bottom gate & top contact geometry, bottom gate & bottom contact geometry, top gate & bottom contact geometry, and top gate & top contact geometry (51).

In one or more embodiments, a plurality of the OFETs are solution processed onto a substrate from a same batch of solution comprising the semiconducting polymers. In one or more embodiments, the semiconducting polymers are deposited from solution onto a substrate to form a film comprising the semiconducting polymers, wherein a plurality of source contacts, a plurality of drain contacts, and a plurality of gate contacts are patterned/formed onto the film to form a plurality of the OFETs each comprising one of the sources, one of the drains, and one of the gates. In one or more embodiments, a plurality of such OFETs (e.g., 50 OFETs) have a mean mobility between 1 and 100 cm²V⁻¹ s⁻¹ with a standard deviation of 13 cm²V⁻¹ s⁻¹ or less.

In one or more embodiments, the OFET comprises means (e.g., grooves, nanogrooves or statutory equivalents thereof) for aligning the main chain axes to the channel. In one or more embodiments, the semiconductor polymers in the OFET each comprise polymer chains, the polymer chains each having a backbone/main chain axis, the semiconducting polymers stacked in one or more fibers (e.g., each having a width or diameter of 2 nm-3 nm), and the fibers bundled into fiber bundles. Each fiber bundle has a long axis and a short axis, and the main-chain axes are aligned along the long-axis of the fiber while π-π stacking of the polymer chains is in a direction along the short-axis of the fiber. In one or more embodiments, the nanogrooves contact and align one or more of the fibers such that the fibers are continuously aligned with (and/or at least partially lie within) one or more of the nanogrooves. Fibers on the nanostructured/nanogrooved substrate can form fiber bundles having a width of 50-100 nm (as compared to fiber bundles having a width between 30-40 nm when fabricated on a non-structured substrate).

In one or more embodiments, the semiconducting polymers comprise aligned conjugated polymer chains stacked to form a crystalline structure, the polymer chains oriented with an orientational order parameter between 0.9 and 1.

The nanogrooves align the semiconducting polymers such that conduction between the source contact and the drain contact is predominantly along the backbones/main chain axes parallel to a longitudinal axis of at least one of the nanogrooves, although charge hopping between adjacent polymers in a fiber bundle is also possible. For example, the means can align the main chain axes to an imaginary line bounded by the source and the drain or the means can align the main chain axes to an alignment direction 1310 in the channel between Source S and Drain D.

In one or more embodiments, the dielectric layer is patterned with the nanogrooves that orient the semiconducting polymers.

In other embodiments, means for aligning the semiconducting polymers comprises a fabrication method, including, but not limited to, blade coating, dip coating, and bar coating (or statutory equivalents thereof) of the semiconducting polymers on dielectric/substrate.

In one or more embodiments, the semiconducting polymers are fabricated as active regions in devices other than OFETs, such as in an organic light emitting device or in a photovoltaic cell.

In one or more embodiments, the fabrication of the OFET, including selection of one or more compositions, one or more structures, and one or more configurations of the source, the drain, the gate, the dielectric, and/or the SAM; selection of a composition, structure (including regioregularity), crystallinity, and/or stability of the semiconducting polymers; selection of the solution casting conditions (e.g., solvent composition, casting speed) and annealing conditions (e.g., annealing time and/or temperature) for fabrication of the film comprising the semiconducting polymers; and selection of the quality and/or morphology of the film, are such that:
one or more threshold voltages of the one or more OFETs are within +/−1 volt (V) of 0 V;
one or more of the threshold voltages are equal to zero or shifted back towards zero;
variability of the one or more threshold voltages is reduced (e.g., twenty or fifty of the OFETs have an average threshold voltage within +/−1 V of 0 V);
each of the OFETs are characterized by having a threshold voltage that is stable (e.g., within +/−1 V of zero volts) after multiple sweeps of the gate source voltage;
each of the OFETs are characterized by having a stable threshold voltage at various operating voltages (e.g., the threshold voltage of each of the OFETs is within +/−1 V of zero volts when the gate source voltage varies between −120 V to −0.5 V).
one or more carrier mobilities (e.g., hole and/or electron mobilities) of the one or more OFETs are between 28 cm² V⁻¹ s⁻¹ and at least 97 cm² V⁻¹ s⁻¹ (e.g., at least 40 cm² V⁻¹ s⁻¹ or at least 97 cm² V⁻¹ s⁻¹) in a saturation regime;
hole and/or electron mobility is in a range of 28.1 cm² V⁻¹ s⁻¹-200 cm² V⁻¹ s⁻¹, or between 28.1 cm² V⁻¹ s⁻¹-100 cm² V⁻¹ s⁻¹, e.g., for a source drain voltage in a range of −120 V to 1 V and a gate-source voltage in a range of +20 V to −80 V, or for a gate-source voltage in a range of −20 V to −40 V at a source-drain voltage of −120V);
the OFETs' mobility is not dependent on blade coating direction and/or the semiconducting polymers are not aligned (or there is no clear alignment of the semiconducting polymers as measured in top surface of an AFM image of the semiconducting polymers) and/or the OFETs each have a hole and/or electron mobility of at least 1.2 cm² V⁻¹ s⁻¹ (or at least 0.03 cm² V⁻¹ s⁻¹ after 5 days exposure to air).
the carrier mobilities of fifty or less of the OFETs have an average (e.g., average field effect hole or field electron mobility in the saturation regime) of at least 65 cm² V⁻¹ s⁻¹;
one or more of the OFETs have their carrier mobility reduced by less than 12% or less than 20% as exposure of the OFETs is increased from 4 hours to 100 hours in ambient air at a temperature of 22° C.-30° C., the ambient air having a relative humidity of 45%-70%, and the exposure including 50 hours in a nitrogen ambient; and/or
the semiconducting polymers have higher average mobility and higher stability in ambient air as compared to PCDTPT or PBT.

Moreover, the fabrication can be under conditions wherein the semiconducting polymer comprises aligned conjugated polymer chains stacked to form a crystalline structure. In one or more embodiments, a π-π stacking of the semiconducting polymer in the film is characterized by a peak having a full width at half maximum of 2 nm⁻¹ or less, as measured by a grazing incidence wide-angle X-ray scattering (GIWAXS) measurement of the film. In one or more embodiments, a π-π distance between adjacent polymer chains is no more than 0.35 nm.

The above described crystallinity and OFET performance can be achieved using the semiconducting polymers fabricated using the synthesis procedure described in FIG. 1 and the associated text.

Thus, one or more embodiments of the present invention have discovered that semiconducting polymers with fluoro functionality have unique combinations of properties. Specifically, the present disclosure has unexpectedly and surprisingly discovered that some fluorinated semiconducting polymers with specific fluorine moieties (e.g., P2F or PCDTFBT) can be used to fabricate OFETs having increased stability in air, threshold voltage closer to zero, high on/off ratio, and less variation in performance (e.g., mobility and threshold voltage) between devices, while the OFETs have mobility that is at least comparable to OFETs fabricated using PCDTPT or PBT. The discovery is unexpected and surprising because some fluorinated polymers (e.g., PDF) had reduced mobility. Furthermore, it was unexpectedly and surprisingly discovered that molecular structure of the fluorinated semiconducting polymers appeared to have no influence on the alkyl chain or π-π stacking distance of the semiconducting polymers.

The relative stability of the fluorinated polymers enables fabrication of devices that could not previously have been envisaged. For example, batch processing or flow processing can be used to fabricate the OFETs. Moreover, a plurality (e.g., at least 50) of OFETs having the above described desirable, unique, and discovered properties can be mass produced (e.g., each from the same batch or the same solution comprising the semiconducting polymers). An optoelectronic (e.g., display) or electronic device comprising a plurality of the OFETs can be fabricated. Other devices or systems requiring a plurality of stable OFETs (e.g., stable threshold voltage ˜0 V), such as sensor systems, can also be fabricated.

Device Embodiments

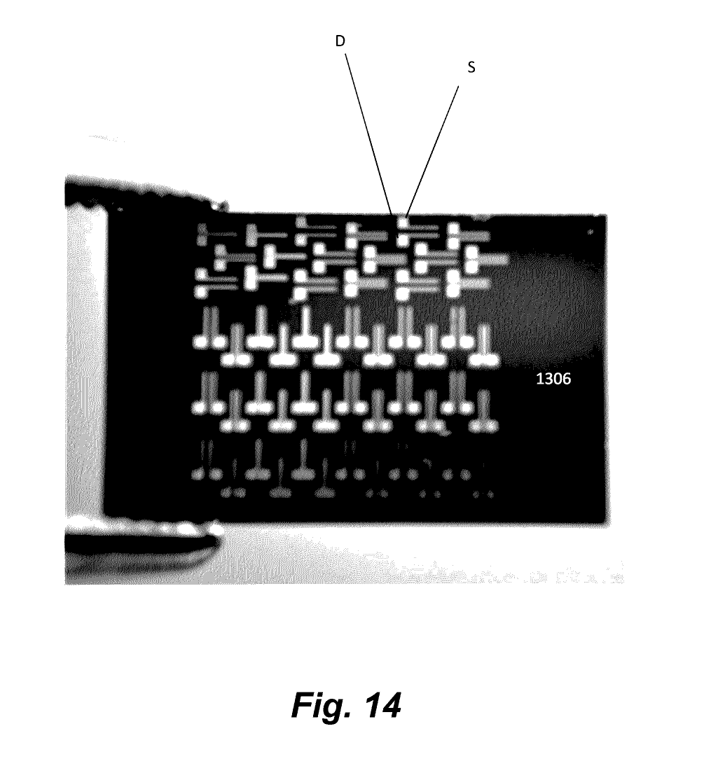

FIG. 14 illustrates a device comprising storage (e.g., a substrate 1306 and/or package 1308) for a plurality of the OFETs each comprising a source S, a drain D, and a gate (e.g., at least twenty or at least fifty of the OFETs). The storage (e.g., air permeable package) exposes the semiconducting polymers to air. In one or more embodiments, the device 1300 comprises an optoelectronic or electronic device storing the OFETs in a circuit. In one or more embodiments, the OFETs do not comprise encapsulation layers or the semiconducting polymers are covered by layers permeable to air. In one or more embodiments, the device 1300 further comprises electrical connections and/or voltage sources to bias the OFETs with the appropriate threshold voltages and source-drain voltages to achieve the desired mobility and/or performance stability, and outputs to receive the outputs from each of the OFETs. In one or more embodiments, the OFETs are connected in a circuit to form logic gates. In one or more embodiments, the device comprises a display or array of sensors comprising the logic gates. The relative consistent performance of the OFETs fabricated according one or more embodiments of the present invention enables fabrication of a circuit comprising electrical connections switching a plurality (e.g., at least 50) OFETs on or off using a gate-source voltage (from a voltage supply) that is greater than or less than the threshold voltage of the OFETs (wherein the threshold voltage of all the OFETs is zero volts or within +/−1 of zero volts).

### ADVANTAGES AND IMPROVEMENTS

As we described above, despite successes in achieving high charge carrier mobilities, copolymers containing CDT and BT structural units exhibit relatively high-lying highest occupied molecular orbital (HOMO) levels (−5.0±0.2 eV) (34); not an ideal situation for long-term air stability (below −5.27 eV) (35). For structures containing the more electron withdrawing PT fragments, the basic nature of the PT heterocycle can de-stabilize relevant electronic properties when exposed to air or acidic surfaces (7, 36). Based on the above concerns, one or more embodiments of the present invention sought to design D-A copolymers containing CDT in conjunction fluorine-substituted BT derivatives as the acceptor. This approach was anticipated to lower the orbital levels of the resulting polymers and improve stability both in OFET and optoelectronic devices (37).

Indeed, one or more embodiments of the present invention achieve a hole mobility of a highly aligned semiconducting polymer, P2F or PCDTFBT (see FIGS. 1 and 5(a) for molecular structure) approaching 100 cm²/V-s, the highest value (a record) for semiconducting polymers reported to date. In addition, through a comparative study of FETs fabricated with PCDTPT and its fluorinated analogue (P2F or PCDTFBT), one or more embodiments of the present invention show that simple fluorination leads to remarkable air-stability and reliable transistor characteristics. FETs fabricated from aligned PCDTFBT yielded stable threshold voltages near zero volt and a distribution of saturation hole mobilities with average value of 76 cm²/V-s and maximum value of i=97 cm²/V-s (50 independent FETs). High mobility is retained over 100 hours in ambient air without any encapsulation layers. Our results represent important progress for solution-processed plastic transistors, and provide molecular design guidelines for high-mobility and air-stable semiconducting polymers.

Since the FET is the most important circuit element in modern electronics, the high values of the mobility and stability reported here will enable “plastic” transistors to be processed from solution at low cost. Moreover, the results obtained in this disclosure are reproducible. The dimensions of the solution processed FETs can be reduced to sizes that are consistent with industrial product needs.

### REFERENCES

The following references are incorporated by reference herein.
1. A. J. Heeger, Semiconducting polymers: the Third Generation, Chem. Soc. Rev. 39, 2354-2371 (2010).
2. B. B.-Y. Hsu et al., The density of states and the transport effective mass in a highly oriented semiconducting polymer: Electronic delocalization in 1D, Adv. Mater., 10.1002/adma.201502820 (2015).
3. L. Ying et al., Regioregular pyridal[2,1,3]thiadiazole π-conjugated copolymers, J. Am. Chem. Soc. 133, 18538-18541 (2011).
4. H.-R. Tseng et al., High mobility field effect transistors based on macroscopically oriented regioregular copolymers, Nano Lett. 12, 6353-6357 (2012).
5. H.-R. Tseng et al., High-mobility field-effect transistors fabricated with macroscopic aligned semiconducting polymers, Adv. Mater. 26, 2993-2998 (2014).
6. C. Luo et al., General strategy for self-assembly of highly oriented nanocrystalline semiconducting polymers with high mobility, Nano Lett. 14, 2764-2771 (2014).
7. B. H. Lee, G. C. Bazan, A. J. Heeger, Doping-Induced Carrier Density Modulation in Polymer Field-Effect Transistors, Adv. Mater., 10.1002/adma.201504307 (2015).
8. T. S. van der Poll, J. A. Love, T.-Q. Nguyen, G. C. Bazan, Non-basic high-performance molecules for solution-processed organic solar cells, Adv. Mater. 24, 3646-3649 (2012).
9. Y. K. Sharma, S. C. Mathur, D. C. Dube, S. P. Tandon, Optical absorption spectra and energy band gap in praseodymium borophosphate glasses, J. Mater. Sci. Lett. 14, 71-73 (1995).
10. http://www.lasurface.com/database/elementxps.php.
11. S. Cho et al., A thermally stable semiconducting polymer, Adv. Mater. 22, 1253-1257 (2010).
12. L. A. Perez et al., Effect of backbone regioregularity on the structure and orientation of a donor-acceptor semiconducting copolymer, Macromolecules 47, 1403-1410 (2014).
13. S. N. Patel et al., NEXAFS spectroscopy reveals the molecular orientation in blade-coated pyridal[2,1,3]thiadiazole-containing conjugated polymer thin films, Macromolecules 48, 6606-6616 (2015).
14. G. Kim et al., A thienoisoindigo-naphthalene polymer with ultrahigh mobility of 14.4 cm2/V·s that substantially exceeds benchmark values for amorphous silicon semiconductors, J. Am. Chem. Soc. 136, 9477-9483 (2014).
15. I. Kang et al., Record high hole mobility in polymer semiconductors via side-chain engineering, J. Am. Chem. Soc. 135, 14896-14899 (2013).
16. J. Li et al., A stable solution-processed polymer semiconductor with record high-mobility for printed transistors, Sci. Rep. 2, (2012).
17. Y. Yamashita et al., Transition between band and hopping transport in polymer field-effect transistors, Adv. Mater. 26, 8169-8173 (2014).
18. H. Chen et al., Highly π-extended copolymers with diketopyrrolopyrrole moieties for high-performance field-effect transistors, Adv. Mater. 24, 4618-4622 (2012).
19. J. Lee et al., Thin Films of Highly Planar Semiconductor Polymers Exhibiting Band-like Transport at Room Temperature, J. Am. Chem. Soc. 137, 7990-7993 (2015).
20. S. V. Rakhmanova, E. M. Conwell, Electric-field dependence of mobility in conjugated polymer films, Appl. Phys. Lett. 76, 3822-3824 (2000).
21. I. McCulloch et al., Liquid-crystalline semiconducting polymers with high charge-carrier mobility, Nat. Mater. 5, 328-333 (2006).
22. S. Cho, K. Lee, A. J. Heeger, Extended lifetime of organic field-effect transistors encapsulated with titanium sub-oxide as an ‘active’ passivation/barrier Layer, Adv. Mater. 21, 1941-1944 (2009).
23. P. A. Bobbert et al., Operational stability of organic field-effect transistors, Adv. Mater. 24, 1146-1158 (2012).
24. K. Lee et al., Air-stable polymer electronic devices, Adv. Mater. 19, 2445-2449 (2007).
25. R. Schmidt et al., Core-fluorinated perylene bisimide dyes: Air stable n-channel organic semiconductors for thin film transistors with exceptionally high on-to-off current ratios, Adv. Mater. 19, 3692-3695 (2007).
26. H. Z. Chen et al., Air stable n-channel organic semiconductors for thin film transistors based on fluorinated derivatives of perylene diimides, Chem. Mater. 19, 816-824 (2007).
27. H. E. Katz et al., A soluble and air-stable organic semiconductor with high electron mobility, Nature 404, 478-481 (2000).
28. (a) C. D. Dimitrakopoulos and P. R. L. Malenfant, Adv. Mater., 2002, 14, 99-117; (b) A. C. Arias, J. D. MacKenzie, I. McCulloch, J. Rivnay and A. Salleo, Chem. Rev., 2010, 110, 3-24.
29. (a) J. Li, Y. Zhao, H. S. Tan, Y. L. Guo, C. A. Di, G. Yu, Y. Q. Liu, M. Lin, S. H. Lim, Y. H. Zhou, H. B. Su and B. S. Ong, Sci. Rep., 2012, 2, 754-764; (b) I. Kang, H. J. Yun, D. S. Chung, S. K. Kwon and Y. H. Kim, J. Am. Chem. Soc., 2013, 135, 14896-14899; (c) G. Kim, S. J. Kang, G. K. Dutta, Y. K. Han, T. J. Shin, Y. Y. Noh and C. Yang, J. Am. Chem. Soc., 2014, 136, 9477-9483; (d) H. R. Tseng, H. Phan, C. Luo, M. Wang, L. A. Perez, S. N. Patel, L. Ying, E. J. Kramer, T. Q. Nguyen, G. C. Bazan and A. J. Heeger, Adv. Mater., 2014, 26, 2993-2998. (e) Y. Diao, B. C. K. Tee, G. Giri, J. Xu, D. H. Kim, H. A. Becerril, R. M. Stoltenberg, T. H. Lee, G. Xue, S. C. B. Mannsfeld and Z. N. Bao, Nat. Mater., 2013, 12, 665-671. (f) Y. B. Yuan, G. Girl, A. L. Ayzner, A. P. Zoombelt, S. C. B. Mannsfeld, J. H. Chen, D. Nordlund, M. F. Toney, J. S. Huang and Z. N. Bao, Nat. Commun., 2014, 5, 3005.
30. (a) L. Biniek, B. C. Schroeder, C. B. Nielsen and I. McCulloch, J. Mater. Chem., 2012, 22, 14803-14813; (b) J. G. Mei, Y. Diao, A. L. Appleton, L. Fang and Z. N. Bao, J. Am. Chem. Soc., 2013, 135, 6724-6746; (c) Y. Olivier, D. Niedzialek, V. Lemaur, W. Pisula, K. Müllen, U. Koldemir, J. R. Reynolds, R. Lazzaroni, J. Cornil and D. Beljonne, Adv. Mater., 2014, 26, 2119-2136.
31. M. Zhang, H. N. Tsao, W. Pisula, C. D. Yang, A. K. Mishra and K. Mullen, J. Am. Chem. Soc., 2007, 129, 3472-3473.
32. (a) H. N. Tsao, D. Cho, J. W. Andreasen, A. Rouhanipour, D. W. Breiby, W. Pisula and K. Müllen, Adv. Mater., 2009, 21, 209-212; (b) S. H. Wang, M. Kappl, I. Liebewirth, M. Muller, K. Kirchhoff, W. Pisula and K. Müllen, Adv. Mater., 2012, 24, 417-420; (c) Y. Yamashita, J. Tsurumi, F. Hinkel, Y. Okada, J. Soeda, W. Zajaczkowski, M. Baumgarten, W. Pisula, H. Matsui, K. Müllen and J. Takeya, Adv. Mater., 2014, 26, 8169-8173.
33. L. Ying, B. B. Y. Hsu, H. M. Zhan, G. C. Welch, P. Zalar, L. A. Perez, E. J. Kramer, T. Q. Nguyen, A. J. Heeger, W. Y. Wong and G. C. Bazan, J. Am. Chem. Soc., 2011, 133, 18538-18541.
34. (a) R. C. Coffin, J. Peet, J. Rogers and G. C. Bazan, Nat. Chem., 2009, 1, 657-661; (b) C. K. Mai, H. Q. Zhou, Y. Zhang, Z. B. Henson, T. Q. Nguyen, A. J. Heeger and G. C. Bazan, Angew. Chem. Int. Ed., 2013, 52, 12874-12878; (c) Y. Zhang, J. Y. Zou, C. C. Cheuh, H. L. Yip and A. K. Y. Jen, Macromolecules, 2012, 45, 5427-5435.
35. (a) D. M. deLeeuw, M. M. J. Simenon, A. R. Brown and R. E. F. Einerhand, Synth. Met., 1997, 87, 53-59; (b) N. Blouin, A. Michaud, D. Gendron, S. Wakim, E. Blair, R. Neagu-Plesu, M. Belletete, G. Durocher, Y. Tao and M. Leclerc, J. Am. Chem. Soc., 2008, 130, 732-742.
36. (a) T. S. van der Poll, J. A. Love, T. Q. Nguyen and G. C. Bazan, Adv. Mater., 2012, 24, 3646-3649; (b) H. Q. Zhou, Y. Zhang, C. K. Mai, J. Seifter, T. Q. Nguyen, G. C. Bazan and A. J. Heeger, ACS Nano, 2015, 9, 371-377.
37. (a) K. Takimiya, T. Yamamoto, H. Ebata, T. Izawa, Sci. Technol. Adv. Mater., 2007, 8, 273-276; (b) W. M. Zhang, J. Smith, S. E. Watkins, R. Gysel, M. McGehee, A. Salleo, J. Kirkpatrick, S. Ashraf, T. Anthopoulos, M. Heeney and I. McCulloch, J. Am. Chem. Soc., 2010, 132, 11437-11439.
38. L. A. Perez, P. Zalar, L. Ying, K. Schmidt, M. F. Toney, T. Q. Nguyen, G. C. Bazan and E. J. Kramer, Macromolecules, 2014, 47, 1403-1410.
39. H. R. Tseng, L. Ying, B. B. Y. Hsu, L. A. Perez, C. J. Takacs, G. C. Bazan and A. J. Heeger, Nano Lett., 2012, 12, 6353-6357.
40. C. M. Cardona, W. Li, A. E. Kaifer, D. Stockdale and G. C. Bazan, Adv. Mater., 2011, 23, 2367-2371.
41. R. L. Uy, S. C. Price and W. You, Macromol. Rapid Commun., 2012, 33, 1162-1177.
42. S. N. Patel, G. M. Su, C. Luo, M. Wang, L. A. Perez, D. A. Fischer, D. Prendergast, G. C. Bazan, A. J. Heeger, M. L. Chabinyc and E. J. Kramer, Macromolecules, 2015, 48, 6606-6616.
43. J. Zaumseil and H. Sirringhaus, Chem. Rev., 2007, 107, 1296-1323.
44. Y. Zhao, Y. L. Guo and Y. Q. Liu, Adv. Mater., 2013, 25, 5372-5391.
45. D. Venkateshvaran, M. Nikolka, A. Sadhanala, V. Lemaur, M. Zelazny, M. Kepa, M. Hurhangee, A. J. Kronemeijer, V. Pecunia, I. Nasrallah, I. Romanov, K. Broch, I. McCulloch, D. Emin, Y. Olivier, J. Cornil, D. Beljonne and H. Sirringhaus, Nature, 2014, 515, 384-388.
46. (a) Z. H. Chen, P. Cai, J. W. Chen, X. C. Liu, L. J. Zhang, L. F. Lan, J. B. Peng, Y. G. Ma and Y. Cao, Adv. Mater., 2014, 26, 2586-2591; (b) X. F. Liu, B. B. Y. Hsu, Y. M. Sun, C. K. Mai, A. J. Heeger and G. C. Bazan, J. Am. Chem. Soc., 2014, 136, 16144-16147.
47. H. Bronstein, J. M. Frost, A. Hadipour, Y. Kim, C. B. Nielsen, R. S. Ashraf, B. P. Rand, S. Watkins, I. McCulloch, Chem. Mater., 2013, 25, 277-285.
48. (a) Rivnay, J.; Mannsfeld, S. C.; Miller, C. E.; Salleo, A.; Toney, M. F. Chem. Rev., 2012, 112, 5488-5519; (b) Chabinyc, M. L. Polym. Rev., 2008, 48, 463-492.
49. Supplementary Information entitled “Fluorine Substitution Influence on Benzo[2,1,3]thiodiazole Based Polymers for Field-Effect Transistor Applications,” by Ming Wang, Michael Ford, Hung Phan, Jessica Coughlin, Thuc-Quyen Nguyen, and Guillermo C. Bazan, found at pages S-1 to S-13 or pages 6-18 of the priority application for the present application (U.S. Provisional Patent Application 62/253,975).
50. Supplementary Information containing supplementary Figures S1-S7 and Scheme Si, entitled “Supplementary Information: Semiconducting polymers with mobility approaching 100 cm²/V-s,” by Byoung Hoon Lee, Ben B. Y. Hsu, Shrayesh N. Patel, Chan Luo, Yali Yang, Steven Xiao, Guillermo C. Bazan, and Alan J. Heeger, found in the Appendix of the specification of the priority application for the present application (U.S. Provisional Patent Application 62/263,058).
51. DiBenedetto et. al., Molecular Self-Assembled Monolayers and Multilayers for Organic and Unconventional Inorganic Thin-Film Transistor Applications, Adv. Mater. 2009, 21, 1407-1433 DOI 10.1002/adma.200803267.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. One or more organic field effect transistors (OFETs), wherein each of the OFETs comprises:
a channel comprising semiconducting polymers, wherein:
each of the semiconducting polymers have a conjugated main chain section having a repeating unit of the structure: 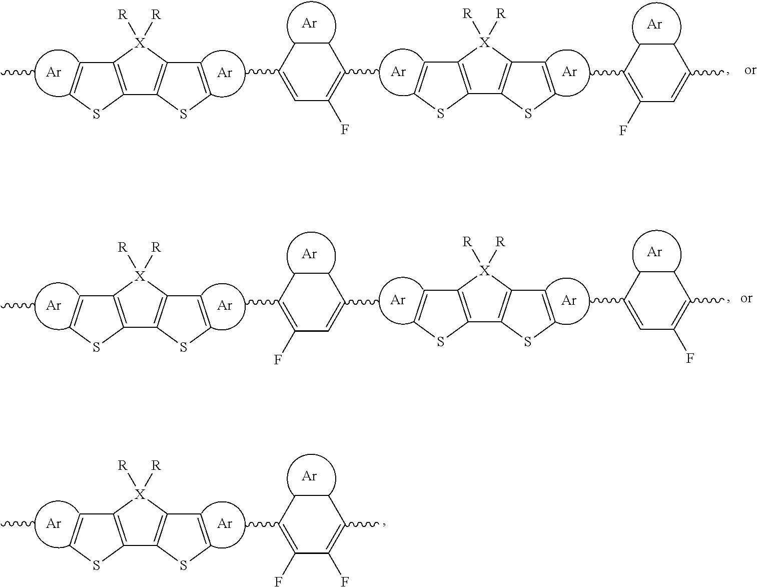
Ar is a substituted or non-substituted aromatic functional group containing one, two, three or more aromatic rings, or Ar is nothing and the valence of the ring comprising fluorine (F) is completed with hydrogen,
each Ar is independently a substituted or non-substituted aromatic functional group, or each Ar is independently nothing and the valence of its respective ring is completed with hydrogen,
each R is independently hydrogen or a substituted or non-substituted alkyl, aryl or alkoxy chain; and
X is C, Si, Ge, N or P;
a source contact to the channel;
a drain contact to the channel; and
a gate contact on or above the channel.

2. The OFETs of claim 1, wherein each of the semiconducting polymers have a repeating unit of the structure: 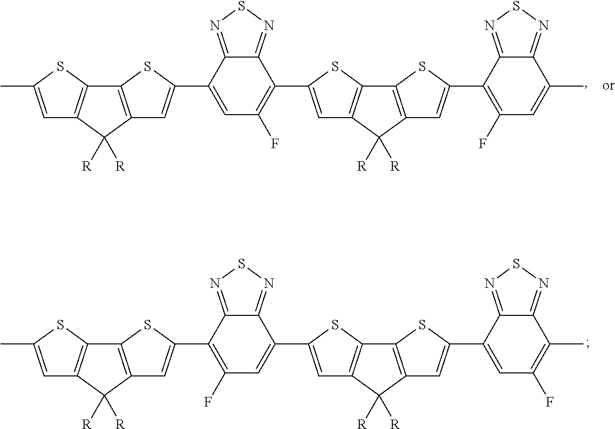
and
wherein the fluorine (F) is regioregularly arranged along the semiconducting polymer's conjugated main chain section.

3. The OFETs of claim 1, wherein the acceptor structure is selected from FIG. 11.

4. The OFETs of claim 1, wherein:
the semiconducting polymers are disposed in a film on a planar, non-grooved surface, and
the film has a crystallinity characterized by the OFETs each having a hole mobility of at least 1.2 cm²V⁻¹ s⁻¹ in a saturation regime.

5. The OFETs of claim 4, the hole mobility is in a range of 1.2-10 cm²V⁻¹ s⁻¹ in the saturation regime.

6. The OFETs of claim 1, wherein the semiconducting polymers are on a grooved surface and the semiconducting polymers have an alignment with respect to each other characterized by the OFETs each having a hole mobility between 1 cm² V⁻¹ s⁻¹ and 97 cm² V⁻¹ s⁻¹ in a saturation regime.

7. The OFETs of claim 6, wherein the OFETs each have a threshold voltage within +/−1 volt of zero volts.

8. The OFETs of claim 7, wherein the OFETs each have a threshold voltage of zero volts.

9. The OFETs of claim 6, wherein the semiconducting polymers comprise aligned conjugated polymer chains stacked to form a crystalline structure, the polymer chains oriented with an orientational order parameter between 0.9 and 1.

10. The OFETs of claim 6, wherein a π-π stacking of the semiconducting polymer chains in the film is characterized by a peak having a full width at half maximum of 2 nm⁻¹ or less, as measured by a grazing incidence wide-angle X-ray scattering (GIWAXS) measurement of the film.

11. The OFETs of claim 6, wherein a π-π distance between adjacent polymer chains is no more than 0.35 nm.

12. A device comprising storage for twenty of the OFETs of claim 1, wherein each of the OFETs are characterized by:
a threshold voltage such that an average threshold voltage for the twenty OFETs is within +/−1 volt of zero volts, and/or
the threshold voltage that is within +/−1 V of zero volts) after multiple sweeps of the gate source voltage, and/or
the threshold voltage within +/−1 V of zero volts when the gate source voltage varies between −120 V to −0.5 V.

13. A device comprising storage for fifty of the OFETs of claim 1, wherein each of the OFETs are characterized by:
a threshold voltage such that an average threshold voltage for the twenty OFETs is within +/−1 volt of zero volts, and/or
the threshold voltage that is within +/−1 V of zero volts) after multiple sweeps of the gate source voltage, and/or
the threshold voltage within +/−1 V of zero volts when the gate source voltage varies between −120 V to −0.5 V.

14. The device of claim 13, wherein a stability of each of the OFETs is further characterized by the fifty OFETs having an average carrier mobility of at least 65 cm² V⁻¹ s⁻¹ in a saturation regime.

15. A device comprising storage for the OFETs of claim 1, wherein the storage exposes the semiconducting polymers to air.

16. The device of claim 15, wherein:
the device comprises an optoelectronic or electronic device storing the OFETs in a circuit, and
the OFETs do not comprise encapsulation layers or the semiconducting polymers are covered by layers permeable to air.

17. The device of claim 16, wherein:
a carrier mobility of each of the OFETs is reduced by less than 20% as exposure of the OFETs is increased from 4 hours to 100 hours in ambient air at a temperature of 22° C.-30° C., the ambient air having a relative humidity of 45%-70%, and the exposure including 50 hours in a nitrogen ambient.

18. The device of claim 15, wherein carrier (hole and/or electron) mobility of each of the OFETs is at least 0.03 cm²V⁻¹ s⁻¹ after exposure to the air for 5 days.

19. The OFETs of claim 1, wherein the source and drain contacts of the OFETs further comprise a metal oxide electron blocking layer.

20. The OFETs of claim 19, wherein the metal comprises nickel, silver, or Molybdenum.

21. A method of fabricating a plurality of organic field effect transistors, comprising:
providing a source contact and a drain contact to a channel comprising semiconducting polymers; and
providing a dielectric between the semiconducting polymers and a gate; wherein each of the semiconducting polymers have a repeating unit of the structure: 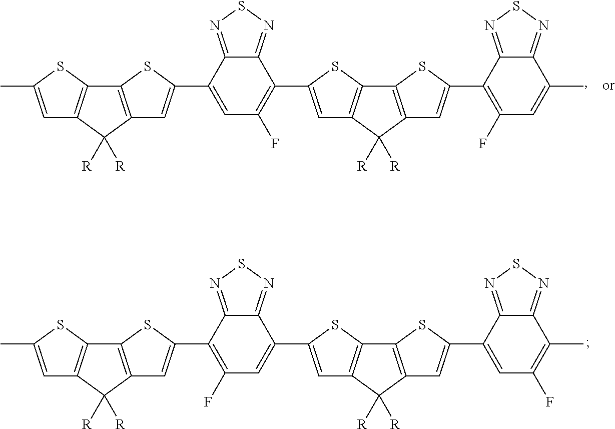
wherein the fluorine (F) is regioregularly arranged along the semiconducting polymer's conjugated main chain section; and
wherein the R are each independently an alkyl, aryl, or an alkoxy chain.

22. The method of claim 21, further comprising solution processing at least fifty of the OFETs onto a substrate from a same batch of solution comprising the semiconducting polymers.
